(19) United States
(12) Patent Application Publication
(10) Pub. No.: US 2015/0333288 A1
(43) Pub. Date: Nov. 19, 2015

(54) ORGANIC ELECTROLUMINESCENT DEVICE, ILLUMINATION APPARATUS, AND ILLUMINATION SYSTEM

(71) Applicant: Kabushiki Kaisha Toshiba, Minato-ku (JP)

(72) Inventors: Keiji SUGI, Fujisawa (JP); Daimotsu KATO, Fuchu (JP); Hayato KAKIZOE, Kawasaki (JP); Tomoaki SAWABE, Sumida (JP); Tomio ONO, Yokohama (JP); Shintaro ENOMOTO, Yokohama (JP)

(73) Assignee: Kabushiki Kaisha Toshiba, Minato-ku (JP)

(21) Appl. No.: 14/810,038

(22) Filed: Jul. 27, 2015

Related U.S. Application Data
(63) Continuation of application No. PCT/JP2013/079633, filed on Oct. 31, 2013.

(30) Foreign Application Priority Data
Feb. 8, 2013 (JP) 2013-023886

(51) Int. Cl. H01L 51/52; H01L 27/32; H05B 33/08; H01L 51/50

(52) U.S. Cl. CPC H01L 51/5225; H01L 51/5212; H01L 51/5228; H01L 51/5024; H01L 51/5088; H01L 51/5092; H01L 51/5271; H01L 27/3279; H01L 27/3251; H01L 51/5246; H01L 51/5234; H01L 27/3258; H05B 33/0896

(57) ABSTRACT

An organic electroluminescent device includes first and second electrode and an organic light-emitting layer. The first electrode has an upper face. The organic light-emitting layer is provided on the upper face. The second electrode is provided on the organic light-emitting layer. The second electrode includes first and second extension parts. The first extension parts extend in a first direction and are arranged in a second direction. The second extension parts extend in the second direction and are arranged in the first direction. When a length of the first extension parts in the second direction is W1, a pitch of the first extension parts is P1, a length of the second extension parts in the first direction is W2, and a pitch of the second extension parts is P2. W1 and P1 satisfy a relationship of W1≦−750(1−W1/P1)(1−W2/P2)+675. W2 and P2 satisfy a relationship of W2≦−−750(1−W1/P1)(1−W2/P2)+675.

### CROSS-REFERENCE TO RELATED APPLICATIONS

This is a continuation application of International Application PCT/JP2013/079633, filed on Oct. 31, 2013; the entire contents of which are incorporated herein by reference.

### FIELD

Embodiments described herein relate generally to an organic electroluminescent device, an illumination apparatus, and an illumination system.

### BACKGROUND

There is an organic electroluminescent device that includes a light transmissive first electrode, a second electrode, and an organic light-emitting layer provided between the first electrode and the second electrode. There is an illumination apparatus using the organic electroluminescent device as a light source. There is an illumination system that includes a plurality of organic electroluminescent devices and a controller configured to control turning on and turning off the plurality of organic electroluminescent devices. The organic electroluminescent device is made to be light transmissive by using a thin-line shaped second electrode, in which a plurality of openings are provided, or using a light transmissive second electrode. An improvement in the visibility of a transmission image is desired in such an organic electroluminescent device.

### BRIEF DESCRIPTION OF THE DRAWINGS

FIGS. 1A and 1B are schematic views showing an organic electroluminescent device according to a first embodiment;

FIGS. 2A to 2D are the tables showing an example of the experimental results;

FIG. 3 is a graph showing an example of the experimental results;

FIGS. 4A to 4D are the tables showing an example of the experimental results;

FIGS. 5A to 5C are graphs showing an example of the experimental results;

FIGS. 6A and 6B are schematic plan views showing an example of the second electrode;

FIG. 7 is a schematic cross-sectional view showing a part of the organic electroluminescent device according to the first embodiment;

FIGS. 8A and 8B are schematic plan views showing a part of another organic electroluminescent device according to the first embodiment;

FIG. 9 is a schematic cross-sectional view showing another organic electroluminescent device according to the first embodiment;

FIGS. 10A to 10C are schematic views showing another organic electroluminescent device according to the first embodiment;

FIGS. 11A and 11B are schematic views showing another organic electroluminescent device according to the first embodiment;

FIGS. 12A to 12C are schematic views showing another organic electroluminescent device according to the first embodiment;

FIGS. 13A and 13B are schematic views showing another organic electroluminescent device according to the first embodiment;

FIG. 14 is a schematic cross-sectional view showing another organic electroluminescent device according to the first embodiment;

FIG. 15 is a schematic view showing an illumination apparatus according to a second embodiment; and

FIGS. 16A and 16B are schematic views showing an illumination system according to a third embodiment.

### DETAILED DESCRIPTION

According to one embodiment, an organic electroluminescent device includes a first electrode, an organic light-emitting layer, and a second electrode. The first electrode has an upper face. The first electrode is light transmissive. The organic light-emitting layer is provided on the upper face. The second electrode is provided on the organic light-emitting layer. The second electrode is light reflective. The second electrode includes a plurality of first extension parts and a plurality of second extension parts. The first extension parts extend in a first direction parallel to the upper face and are arranged in a second direction. The second direction is parallel to the upper face and intersects with the first direction. The second extension parts extend in the second direction and are arranged in the first direction. The second extension parts intersect with each of the first extension parts. When a length of each of the first extension parts in the second direction is set to W1 (micrometer), a pitch of each of the first extension parts is set to P1 (micrometer), a length of each of the second extension parts in the first direction is set to W2 (micrometer), and a pitch of each of the second extension parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

According to another embodiment, an organic electroluminescent device includes a first electrode, an organic light-emitting layer, a second electrode, and a first wiring layer. The first electrode has an upper face. The first electrode is light transmissive. The organic light-emitting layer is provided on the first electrode. The second electrode is provided on the organic light-emitting layer. The second electrode is light transmissive. The first wiring layer is provided between the first electrode and the organic light-emitting layer. The first wiring layer is light reflective. The first wiring layer includes a plurality of first wiring parts and a plurality of second wiring parts. The first wiring parts extend in a first direction parallel to the upper face and are arranged in a second direction. The second direction is parallel to the upper face and intersects with the first direction. The second wiring parts extend in the second direction and are arranged in the first direction. The second wiring parts intersect with each of the first wiring parts. When a length of each of the first wiring parts in the second direction is set to W1 (micrometer), a pitch of each of the first wiring parts is set to P1 (micrometer), a length of each of the second wiring parts in the first direction is set to W2 (micrometer), and a pitch of each of the second wiring parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

According to another embodiment, an organic electroluminescent device includes a first electrode, an organic light-emitting layer, a second electrode, and a first wiring layer. The first electrode has an upper face. The first electrode is light transmissive. The organic light-emitting layer is provided on the first electrode. The second electrode is provided on the organic light-emitting layer. The second electrode is light transmissive. The first wiring layer is provided on the second electrode. The first wiring layer is light reflective. The first wiring layer includes a plurality of first wiring parts and a plurality of second wiring parts. The first wiring parts extend in a first direction parallel to the upper face and are arranged in a second direction. The second direction is parallel to the upper face and intersects with the first direction. The second wiring parts extend in the second direction and are arranged in the first direction. The second wiring parts intersect with each of the first wiring parts. When a length of each of the first wiring parts in the second direction is set to W1 (micrometer), a pitch of each of the first wiring parts is set to P1 (micrometer), a length of each of the second wiring parts in the first direction is set to W2 (micrometer), and a pitch of each of the second wiring parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

According to another embodiment, an organic electroluminescent device includes a first electrode, an organic light-emitting layer, and a second electrode. The first electrode has an upper face. The first electrode is light transmissive. The organic light-emitting layer is provided on the upper face. The second electrode is provided on the organic light-emitting layer. The second electrode is light reflective. The second electrode includes a plurality of first extension parts and a plurality of second extension parts. The first extension parts extend in a first direction parallel to the upper face and are arranged in a second direction. The second direction is parallel to the upper face and intersects with the first direction. The second extension parts extend in the second direction and are arranged in the first direction. The second extension parts intersect with each of the first extension parts. When a length of each of the first extension parts in the second direction is set to W1 (micrometer), a pitch of each of the first extension parts is set to P1 (micrometer), a length of each of the second extension parts in the first direction is set to W2 (micrometer), a pitch of each of the second extension parts is set to P2 (micrometer), and the W1 and the W2 have different values. The W1, the W2, the P1, and the P2 satisfy a relationship of max(W1, W2)≦−750×(1−max(W1/P1, W2/P2))²+675. (1−max(W1/P1, W2/P2))² is not less than 0.55 and not more than 0.80. Each of the W1 and the W2 is not less than 75 μm and not more than 225 μm.

According to another embodiment, an organic electroluminescent device includes a first electrode, an organic light-emitting layer, a second electrode, and a first wiring layer. The first electrode has an upper face. The first electrode is light transmissive. The organic light-emitting layer is provided on the first electrode. The second electrode is provided on the organic light-emitting layer. The second electrode is light transmissive. The first wiring layer is provided between the first electrode and the organic light-emitting layer. The first wiring layer is light reflective. The first wiring layer includes a plurality of first wiring parts and a plurality of second wiring parts. The first wiring parts extend in a first direction parallel to the upper face and are arranged in a second direction. The second direction is parallel to the upper face and intersects with the first direction. The second wiring parts extend in the second direction and are arranged in the first direction. The second wiring parts intersect with each of the first wiring parts. When a length of each of the first wiring parts in the second direction is set to W1 (micrometer), a pitch of each of the first wiring parts is set to P1 (micrometer), a length of each of the second wiring parts in the first direction is set to W2 (micrometer), a pitch of each of the second wiring parts is set to P2 (micrometer), and the W1 and the W2 have different values. The W1, the W2, the P1, and the P2 satisfy a relationship of max(W1, W2)≦−750×(1−max(W1/P1, W2/P2))²+675. (1−max(W1/P1, W2/P2))² is not less than 0.55 and not more than 0.80. Each of the W1 and the W2 is not less than 75 μm and not more than 225 μm.

According to another embodiment, an organic electroluminescent device includes a first electrode, an organic light-emitting layer, a second electrode, and a first wiring layer. The first electrode has an upper face. The first electrode is light transmissive. The organic light-emitting layer is provided on the first electrode. The second electrode is provided on the organic light-emitting layer. The second electrode is light transmissive. The first wiring layer is provided on the second electrode. The first wiring layer is light reflective. The first wiring layer includes a plurality of first wiring parts and a plurality of second wiring parts. The first wiring parts extend in a first direction parallel to the upper face and are arranged in a second direction. The second direction is parallel to the upper face and intersects with the first direction. The second wiring parts extend in the second direction and are arranged in the first direction. The second wiring parts intersect with each of the first wiring parts. When a length of each of the first wiring parts in the second direction is set to W1 (micrometer), a pitch of each of the first wiring parts is set to P1 (micrometer), a length of each of the second wiring parts in the first direction is set to W2 (micrometer), a pitch of each of the second wiring parts is set to P2 (micrometer), and the W1 and the W2 having different values. The W1, the W2, the P1, and the P2 satisfy a relationship of max(W1, W2)≦−750×(1−max(W1/P1, W2/P2))²+675. (1−max(W1/P1, W2/P2))² is not less than 0.55 and not more than 0.80. Each of the W1 and the W2 is not less than 75 μm and not more than 225 μm.

According to another embodiment, an illumination apparatus includes an organic electroluminescent device and a power source. The organic electroluminescent device includes a first electrode, an organic light-emitting layer, and a second electrode. The first electrode has an upper face. The first electrode is light transmissive. The organic light-emitting layer is provided on the upper face. The second electrode is provided on the organic light-emitting layer. The second electrode is light reflective. The second electrode includes a plurality of first extension parts and a plurality of second extension parts. The first extension parts extend in a first direction parallel to the upper face and are arranged in a second direction. The second direction is parallel to the upper face and intersects with the first direction. The second extension parts extend in the second direction and are arranged in the first direction. The second extension parts intersect with each of the first extension parts. The power source is electrically connected to the first electrode and the second electrode and supplies an electric current to the organic light-emitting layer through the first electrode and the second electrode. When a length of each of the first extension parts in the second direction is set to W1 (micrometer), a pitch of each of the first extension parts is set to P1 (micrometer), a length of each of the second extension parts in the first direction is set to W2 (micrometer), and a pitch of each of the second extension parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

According to another embodiment, an illumination apparatus includes an organic electroluminescent device and a power source. The organic electroluminescent device includes a first electrode, an organic light-emitting layer, a second electrode, and a first wiring layer. The first electrode has an upper face. The first electrode is light transmissive. The organic light-emitting layer is provided on the first electrode. The second electrode is provided on the organic light-emitting layer. The second electrode is light transmissive. The first wiring layer is provided between the first electrode and the organic light-emitting layer. The first wiring layer is light reflective. The first wiring layer includes a plurality of first wiring parts and a plurality of second wiring parts. The first wiring parts extend in a first direction parallel to the upper face and are arranged in a second direction. The second direction is parallel to the upper face and intersects with the first direction. The second wiring parts extend in the second direction and are arranged in the first direction. The second wiring parts intersect with each of the first wiring parts. The power source is electrically connected to the first electrode and the second electrode and supplies an electric current to the organic light-emitting layer through the first electrode and the second electrode. When a length of each of the first wiring parts in the second direction is set to W1 (micrometer), a pitch of each of the first wiring parts is set to P1 (micrometer), a length of each of the second wiring parts in the first direction is set to W2 (micrometer), and a pitch of each of the second wiring parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

According to another embodiment, an illumination apparatus includes an organic electroluminescent device and a power source. The organic electroluminescent device includes a first electrode, an organic light-emitting layer, a second electrode, and a first wiring layer. The first electrode has an upper face. The first electrode is light transmissive. The organic light-emitting layer is provided on the first electrode. The second electrode is provided on the organic light-emitting layer. The second electrode is light transmissive. The first wiring layer is provided on the second electrode. The first wiring layer is light reflective. The first wiring layer includes a plurality of first wiring parts and a plurality of second wiring parts. The first wiring parts extend in a first direction parallel to the upper face and are arranged in a second direction. The second direction is parallel to the upper face and intersects with the first direction. The second wiring parts extend in the second direction and are arranged in the first direction. The second wiring parts intersect with each of the first wiring parts. The power source is electrically connected to the first electrode and the second electrode and supplies an electric current to the organic light-emitting layer through the first electrode and the second electrode. When a length of each of the first wiring parts in the second direction is set to W1 (micrometer), a pitch of each of the first wiring parts is set to P1 (micrometer), a length of each of the second wiring parts in the first direction is set to W2 (micrometer), and a pitch of each of the second wiring parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

According to another embodiment, an illumination system includes a plurality of organic electroluminescent devices and a controller. Each of the organic electroluminescent devices includes a first electrode, an organic light-emitting layer, and a second electrode. The first electrode has an upper face. The first electrode is light transmissive. The organic light-emitting layer is provided on the upper face. The second electrode is provided on the organic light-emitting layer. The second electrode is light reflective. The second electrode includes a plurality of first extension parts and a plurality of second extension parts. The first extension parts extend in a first direction parallel to the upper face and are arranged in a second direction. The second direction is parallel to the upper face and intersects with the first direction. The second extension parts extend in the second direction and are arranged in the first direction. The second extension parts intersect with each of the first extension parts. The controller is electrically connected to each of the organic electroluminescent devices and controls to turn on and turn off each of the organic electroluminescent devices. When a length of each of the first extension parts in the second direction is set to W1 (micrometer), a pitch of each of the first extension parts is set to P1 (micrometer), a length of each of the second extension parts in the first direction is set to W2 (micrometer), and a pitch of each of the second extension parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

According to another embodiment, an illumination system includes a plurality of organic electroluminescent devices and a controller. Each of the organic electroluminescent devices includes a first electrode, an organic light-emitting layer, a second electrode, and a first wiring layer. The first electrode has an upper face. The first electrode is light transmissive. The organic light-emitting layer is provided on the first electrode. The second electrode is provided on the organic light-emitting layer. The second electrode is light transmissive. The first wiring layer is provided between the first electrode and the organic light-emitting layer. The first wiring layer is light reflective. The first wiring layer includes a plurality of first wiring parts and a plurality of second wiring parts. The first wiring parts extend in a first direction parallel to the upper face and are arranged in a second direction. The second direction is parallel to the upper face and intersects with the first direction. The second wiring parts extend in the second direction and are arranged in the first direction. The second wiring parts intersect with each of the first wiring parts. The controller is electrically connected to each of the organic electroluminescent devices and controls to turn on and turn off each of the organic electroluminescent devices. When a length of each of the first wiring parts in the second direction is set to W1 (micrometer), a pitch of each of the first wiring parts is set to P1 (micrometer), a length of each of the second wiring parts in the first direction is set to W2 (micrometer), and a pitch of each of the second wiring parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

According to another embodiment, an illumination system includes a plurality of organic electroluminescent devices and a controller. Each of the organic electroluminescent devices includes a first electrode, an organic light-emitting layer, a second electrode, and a first wiring layer. The first electrode has an upper face. The first electrode is light transmissive. The organic light-emitting layer is provided on the first electrode. The second electrode is provided on the organic light-emitting layer. The second electrode is light transmissive. The first wiring layer is provided on the second electrode. The first wiring layer is light reflective. The first wiring layer includes a plurality of first wiring parts and a plurality of second wiring parts. The first wiring parts extend in a first direction parallel to the upper face and are arranged in a second direction. The second direction is parallel to the upper face and intersects with the first direction. The second wiring parts extend in the second direction and are arranged in the first direction. The second wiring parts intersect with each of the first wiring parts. The controller is electrically connected to each of the organic electroluminescent devices and controls to turn on and turn off each of the organic electroluminescent devices. When a length of each of the first wiring parts in the second direction is set to W1 (micrometer), a pitch of each of the first wiring parts is set to P1 (micrometer), a length of each of the second wiring parts in the first direction is set to W2 (micrometer), and a pitch of each of the second wiring parts is set to P2 (micrometer). The W1 and the P1 satisfy a relationship of W1≦−750(1−W1/P1)(1−W2/P2)+675. The W2 and the P2 satisfy a relationship of W2≦−750(1−W1/P1)(1−W2/P2)+675. (1−W1/P1)(1−W2/P2) is not less than 0.55 and not more than 0.80. Each of the W1 and the W2 is not less than 75 μm and not more than 225 μm.

Various embodiments will be described hereinafter with reference to the accompanying drawings.

The drawings are schematic or conceptual; and the relationships between the thicknesses and the widths of portions, the proportions of sizes between portions, etc., are not necessarily the same as the actual values thereof. Also, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

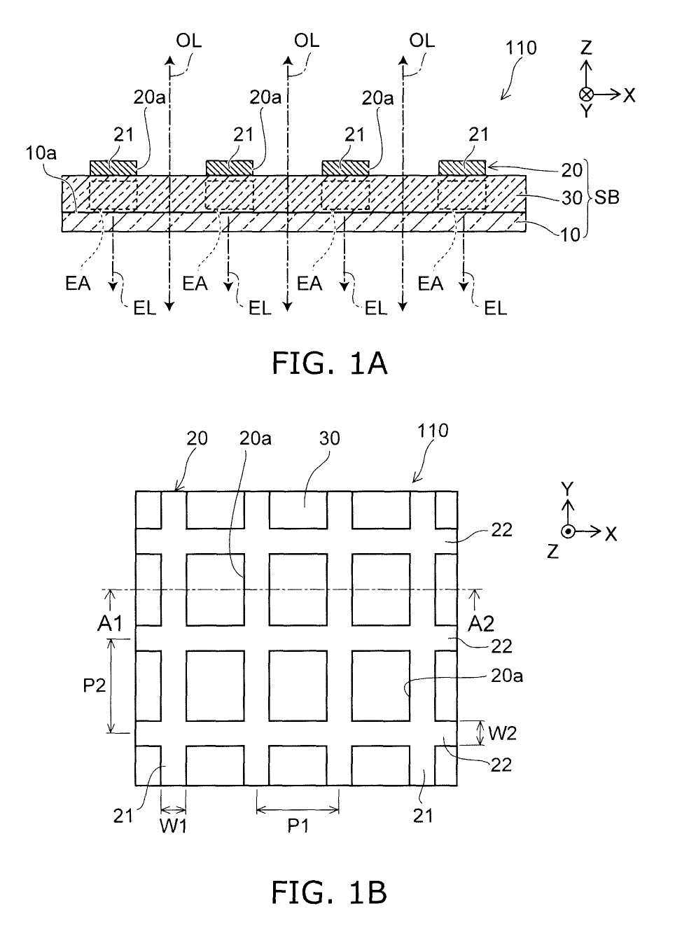

FIGS. 1A and 1B are schematic views showing an organic electroluminescent device according to a first embodiment.

FIG. 1A is a schematic cross-sectional view and FIG. 1B is a schematic plan view.

FIG. 1A is the cross-sectional view along an A1-A2 line of FIG. 1B. These views enlarge and illustrate a part of the organic electroluminescent device according to the embodiment.

As shown in FIGS. 1A and 1B, an organic electroluminescent device 110 includes a stacked body SB. The stacked body SB includes a first electrode 10, a second electrode 20, and an organic light-emitting layer 30.

The first electrode 10 has an upper face 10a. The first electrode 10 is light transmissive. The first electrode 10 is a transparent electrode, for example.

Here, the direction perpendicular to the upper face 10a is defined as a Z-axis direction. One direction parallel to the upper face 10a is defined as an X-axis direction. The direction perpendicular to the X-axis direction and Z-axis direction is defined as a Y-axis direction. The X-axis direction and Y-axis direction are the directions perpendicular to the Z-axis direction. The Z-axis direction corresponds to the thickness direction of the first electrode 10.

The organic light-emitting layer 30 is provided on the upper face 10a of the first electrode 10. The organic light-emitting layer 30 is light transmissive, for example. The organic light-emitting layer 30 is transparent, for example.

The second electrode 20 is provided on the organic light-emitting layer 30. The second electrode 20 includes a plurality of first extension parts 21 and a plurality of second extension parts 22. Each of the plurality of first extension parts 21 extends in a first direction parallel to the upper face 10a and is arranged in a second direction, which is parallel to the upper face 10a and intersects with the first direction. Each of the plurality of second extension parts 22 extends in the second direction, is arranged in the first direction, and intersects with each of the plurality of first extension parts 21. That is, the shape obtained by projecting the second electrode 20 onto a plane (X-Y plane) parallel to the upper face 10a is substantially grid-shaped.

In this example, each of the plurality of first extension parts 21 extends in the Y-axis direction and is arranged in the X-axis direction. Each of the plurality of second extension parts 22 extends in the X-axis direction and is arranged in the Y-axis direction. In this example, the Y-axis direction is the first direction and the X-axis direction is the second direction. In this example, the second direction is substantially perpendicular to the first direction. The second direction may be any direction that intersects with the first direction. Hereinafter, the description will be made, with the Y-axis direction as the first direction and the X-axis direction as the second direction.

The second electrode 20 is a thin film having a substantially uniform thickness, for example. That is, the thickness (the length in the Z-axis direction) of the second electrode 20 in a portion where the first extension part 21 and the second extension part 22 overlap with each other is substantially the same as the thickness (the thickness of the first extension part 21 or the thickness of the second extension part 22) of the second electrode 20 in a portion where the first extension part 21 and the second extension part 22 do not overlap with each other. The thickness of the second electrode 20 in the portion where the first extension part 21 and the second extension part 22 overlap with each other may differ from the thickness of the second electrode 20 in the portion where the first extension part 21 and the second extension part 22 do not overlap with each other. For example, after the respective first extension parts 21 are formed in a stripe shape, the respective second extension parts 22 are formed in a stripe shape on the respective first extension parts 21. As a result, for example, the thickness of the second electrode 20 in the portion where the first extension part 21 and the second extension part 22 overlap with each other may be thicker than the thickness of the second electrode 20 in the portion where the first extension part 21 and the second extension part 22 do not overlap with each other.

The second electrode 20 has a plurality of openings 20a, for example. Each of the plurality of openings 20a is arranged in the X-axis direction and is also arranged in the Y-axis direction. That is, each of the plurality of openings 20a is arranged in a two-dimensional matrix in the X-axis direction and Y-axis direction. Each opening 20a is disposed between each of the first extension parts 21 and between each of the second extension parts 22. Each opening 20a is enclosed, for example, by each first extension part 21 and each second extension part 22 when it is projected onto the X-Y plane. That is, each opening 20a is a portion, where there is neither each first extension part 21 nor each second extension part 22, in the second electrode 20. The opening 20a exposes a part of the organic light-emitting layer 30. A plurality of portions of the organic light-emitting layers 30 are exposed by each of the plurality of openings 20a.

The second electrode 20 (the first extension part 21 and the second extension part 22) is light reflective, for example. The light reflectance of the second electrode 20 is higher than the light reflectance of the first electrode 10. In the specification, a state having a light reflectance higher than the light reflectance of the first electrode 10 is referred to “light reflective”.

The organic light-emitting layer 30 is in contact with the first electrode 10, for example. As a result, the organic light-emitting layer 30 is electrically connected to the first electrode 10. The organic light-emitting layer 30 is electrically connected to the second electrode 20. The organic light-emitting layer 30 is in contact with each of the plurality of first extension parts 21 and each of the plurality of second extension parts 22, for example. As a result, the organic light-emitting layer 30 is electrically connected to the second electrode 20. In the specification, “being electrically connected to” includes “another electrical conductive member being interposed in between” other than “being directly in contact with”.

Electric current is fed into the organic light-emitting layer 30 using the first electrode 10 and the second electrode 20. As a result, the organic light-emitting layer 30 emits light. When electric current flows through the organic light-emitting layer 30, an electron and a hole are recombined to produce an exciter, for example. The organic light-emitting layer 30 emits light utilizing the emission of light during radiative deactivation of the exciter, for example.

In the organic electroluminescent device 110, a portion between the first electrode 10 and the first extension part 21 in the organic light-emitting layer 30 and a portion between the first electrode 10 and the second extension part 22 in the organic light-emitting layer 30 serve as an emission area EA. Electroluminescence EL generated from the emission area EA is emitted to the outside of the organic electroluminescent device 110 through the first electrode 10. A part of the electroluminescence EL is reflected by the second electrode 20, and is then emitted outside through the organic light-emitting layer 30 and first electrode 10. That is, the organic electroluminescent device 110 is of a single-sided light-emitting type.

Moreover, in the organic electroluminescent device 110, external light OL incident from the outside transmits through the first electrode 10 and organic light-emitting layer 30 through the plurality of openings 20a of the second electrode 20. As described above, the organic electroluminescent device 110 causes the external light OL, which is incident on the organic electroluminescent device 110 from the outside, to transmit therethrough while emitting the electroluminescence EL. As described above, the organic electroluminescent device 110 is light transmissive. As a result, in the organic electroluminescent device 110, an image in the background is visible through the organic electroluminescent device 110. That is, the organic electroluminescent device 110 is a see-through type filmy or platy light source.

As described above, the organic electroluminescent device 110 of the embodiment can provide a light transmissive organic electroluminescent device. When the organic electroluminescent device 110 is applied to an illumination apparatus, the function to cause an image in the background to transmit therethrough allows various new applications other than the illumination function.

It is assumed that the width of the first extension part 21 is set to W1, the width of the second extension part 22 to W2, the pitch of each first extension part 21 to P1, and the pitch of each second extension part 22 to P2. The width W1 is the length in the X-axis direction of the first extension part 21. The width W2 is the length in the Y-axis direction of the second extension part 22. The pitch P1 is the center-to-center distance in the X-axis direction of adjacent two first extension parts 21. The pitch P2 is the center-to-center distance in the Y-axis direction of adjacent two second extension parts 22.

In the organic electroluminescent device 110 according to the embodiment, with respect to the width W1 and pitch P1 of each first extension part 21 and the width W2 and pitch P2 of each second extension part 22, the width W1 and pitch P1 of each first extension part 21 satisfy the relationship of W1≦−750(1−W1/P1)(1−W2/P2)+675, and the width W2 and pitch P2 of each second extension part 22 satisfy the relationship of W2≦−750(1−W1/P1)(1−W2/P2)+675. Alternatively, when the width W1 differs from the width W2, they satisfy the relationship of max(W1, W2)≦−750×(1−max(W1/P1, W2/P2))²+675. As a result, the visibility of a transmission image can be increased.

In the light transmissive organic electroluminescent device, the visibility of the second electrode 20 is requested to be reduced. For example, in the light transmissive organic electroluminescent device, there is a configuration in which the second electrodes 20 are formed in a stripe pattern shape. That is, there is a configuration in which the second electrode 20 includes just one of each first extension part 21 and each second extension part 22. In order to reduce the visibility of the second electrode 20 in the stripe pattern-shaped second electrode 20, the width of each extension part is reduced. However, if the width of each extension part is reduced, the area of the emission area is reduced. For example, emission luminance will decrease. Therefore, in order to obtain appropriate emission luminance while reducing the visibility of the second electrode 20 when the second electrodes 20 are formed in a stripe pattern shape, it is necessary to reduce the pitch of each extension part while reducing the width of each extension part. However, if the pitch is reduced, the visibility of a transmission image will decrease. For example, the transmission image will blur. This may be due to the diffraction of light, for example.

Then, the inventors conducted experiments on a relationship between the pattern shape of the second electrode 20 and a decrease in the visibility of a transmission image. Specifically, the inventors conducted experiments on a relationship between the pattern shape of the second electrode 20 and a decrease in the visibility of a transmission image in a case where the pattern shape of the second electrode 20 is grid-shaped.

The inventors first fabricated a plurality of samples, in which the width W1 and pitch P1 of each first extension part 21 of the second electrode 20 and the width W2 and pitch P2 of each second extension part 22 were varied, and conducted experiments on each sample to see whether or not the second electrode 20 is visible. In the sample, a grid-shaped metal thin film is patterned on a glass substrate (hereinafter, the resulting pattern is referred to as a metal pattern). As a result, a shape when the second electrode 20 is projected onto the X-Y plane was simulatively formed. Moreover, in the sample, the width W1 and the width W2 are set to be substantially the same, for convenience. The pitch P1 and the pitch P2 are set to be substantially the same. That is, in the sample, a plurality of substantially-square openings 20a are disposed in a two-dimensional matrix.

The width of one metal line included in the metal pattern is set to Ws. The width Ws corresponds to the width W1 of the first extension part 21 and to the width W2 of the second extension part 22. The pitch of each metal line is set to Ps. The pitch Ps corresponds to the pitch P1 of each first extension part 21 and to the pitch P2 of each second extension part 22. In the experiment, a plurality of samples each having a different width Ws were prepared. Then, for one width Ws, a plurality of samples each having a different pitch Ps were prepared. That is, a plurality of samples each having a different aperture ratio AR=(1−Ws/Ps)² were prepared. Specifically, the width Ws was set to 50 μm, 100 μm, 150 μm, or 200 μm. Then, for each width Ws, the aperture ratio AR was set to 0.55, 0.60, 0.65, 0.70, 0.75, 0.80, 0.85, or 0.90. That is, in the experiment, a total of 32 types of samples were prepared, i.e., four types of width Ws and eight types of aperture ratio AR.

In the experiment, the evaluation was performed for each sample, with a distance L1 between a sample and an examinee set to 1 m, which is the shortest distance assumed from a use state of the organic electroluminescent device 110 according to the embodiment. That is, an illumination apparatus is usually set and used at a position away by not less than 1 m from a sample. In the experiment, there is one examinee. The examinee's eyesight is 1.5. The examinee was caused to face substantially straight a surface, in which a metal pattern is provided, of the sample. In the experiment, the background was uniformly whitened.

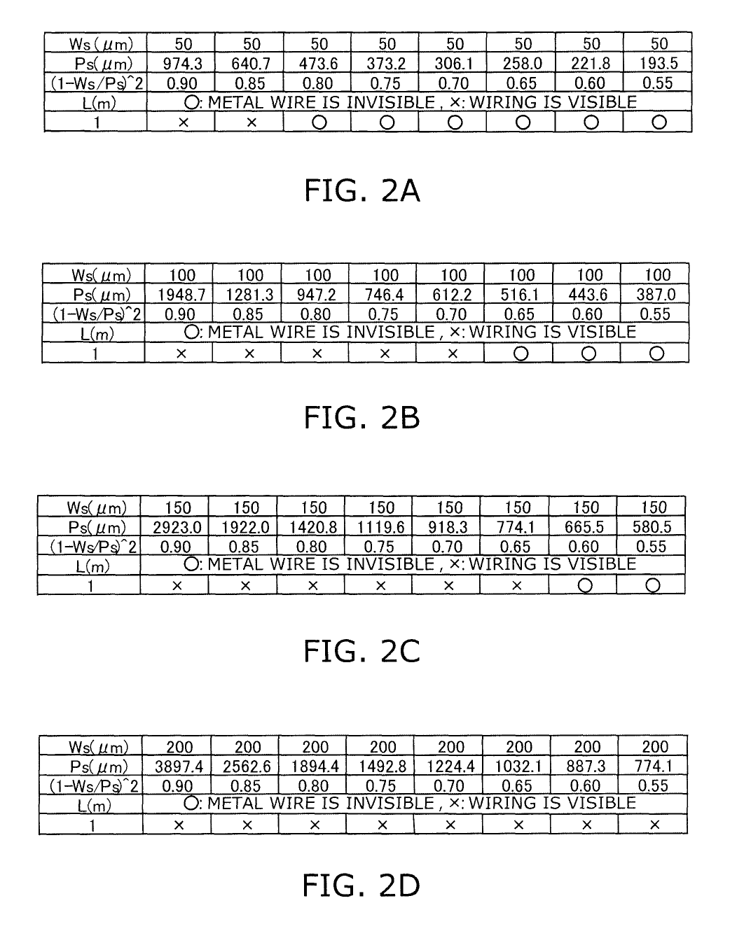

FIGS. 2A to 2D are the tables showing an example of the experimental results.

FIG. 2A shows the evaluation results of each sample in which the width Ws of the metal line was set to 50 μm. FIG. 2B shows the evaluation results of each sample in which the width Ws of the metal line was set to 100 μm. FIG. 2C shows the evaluation results of each sample in which the width Ws of the metal line was set to 150 μm. FIG. 2D shows the evaluation results of each sample in which the width Ws of the metal line was set to 200 μm. In FIGS. 2A to 2D, a sample whose metal line was invisible is marked with “O” while a sample whose metal line was visible is marked with “X”.

Here, the cases where the metal line (the first extension part 21 and the second extension part 22) is “invisible” include, for example, a case where the metal line cannot be recognized as one line due to overlapping with an adjacent line, other than a case where the metal line cannot be perfectly recognized by the human visual sense. That is, in the specification, the “invisible” refers to a state where the pattern shape of each metal line (the first extension part 21 and the second extension part 22) cannot be substantially recognized.

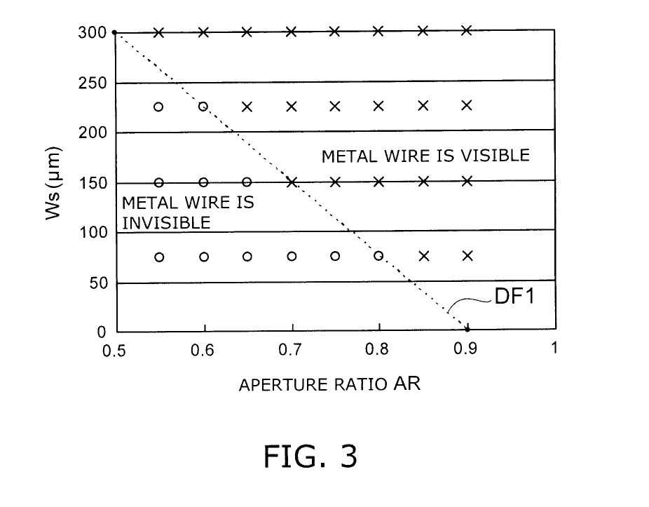

FIG. 3 is a graph showing an example of the experimental results.

In FIG. 3, the results of each table of FIGS. 2A to 2D are collectively plotted. The typical eyesight is 1.0 although the examinee's eyesight is 1.5. According to the human visual features, the visibility of a wiring is determined by the visual angle, and therefore in the plot of FIG. 3, the metal line width Ws is set to 1.5 times the values in FIGS. 2A to 2D assuming the typical eyesight of 1.0. The aperture ratio remains unchanged because the aperture ratio is based on the ratio Ws/Ps.

The visibility of the metal line (the first extension part 21 and the second extension part 22) is not determined just by the width Ws of the metal line or the interval (Ps−Ws) between the metal lines, but depends on both the width Ws of the metal line and the cathode aperture ratio AR=(1−Ws/Ps)² as shown in FIG. 3. FIG. 3 reveals that for example in the case of the aperture ratio AR=0.95, any condition under which the metal line can be made invisible cannot be obtained.

As shown in FIG. 3, the relationship between the width Ws of the metal line and the aperture ratio AR=(1−Ws/Ps)² can be expressed by a direct function DF1. The direct function DF1 is specifically Ws=−750AR+675. In FIG. 3, the left-side region of the direct function DF1 is a region in which the metal line is invisible, while the right-side region of the direct function DF1 is a region in which the metal line is visible. That is, the width Ws and the pitch Ps are set to satisfy the relationship of Ws≦−750AR+675. As a result, the metal line can be made invisible.

In the second electrode 20, the width W1 and pitch P1 of each first extension part 21 are set to satisfy the relationship of W1≦−750AR+675. More specifically, they are set to satisfy the relationship of W1≦−750(1−W1/P1)(1−W2/P2)+675. Then, in the second electrode 20, the width W2 and pitch P2 of each second extension part 22 are set to satisfy the relationship of W2≦−750AR+675. More specifically, the width W2 and pitch P2 of each second extension part 22 are set to satisfy the relationship of W2≦−750(1−W1/P1)(1−W2/P2)+675. As a result, in the second electrode 20, each first extension part 21 and each second extension part 22 can be made invisible.

When the experimental results are based on the examinee's eyesight of 1.5 without adjustment, the direct function DF1 is Ws=−500AR+450. In this case, the width W1 and pitch P1 of each first extension part 21 are set to satisfy the relationship of W1≦−500(1−W1/P1)(1−W2/P2)+450. The width W2 and pitch P2 of each second extension part 22 are set to satisfy the relationship of W2≦−500(1−W1/P1)(1−W2/P2)+450. As a result, in the second electrode 20, each first extension part 21 and each second extension part 22 can be made invisible.

Alternatively, in the case where the width W1 of each first extension part 21 differs from the width W2 of each second extension part 22, the width W1 or width W2 is set to satisfy max(W1, W2)≦−750×(1−max(W1/P1, W2/P2))²+675. Here, max(A, B) designates a larger one of A and B. This is because as shown in FIGS. 2A to 2D, when the width Ws of a metal line is small, the metal line is less visible as compared with the case where the width Ws is large. Even in the cases satisfying these formulas, each first extension part 21 and each second extension part 22 can be made invisible.

As described above, it has been found from the experimental results that the visibility of the metal pattern (the second electrode 20) is not determined just by the width Ws of the metal line or the interval (Ps−Ws) between the metal lines, but depends on both the width Ws of the metal line and the aperture ratio AR. For example, it has been found that reducing the aperture ratio AR makes a metal line less visible. The boundary of a threshold with respect to whether or not a metal line can be seen can be expressed by a substantially direct function in the plane formed by the aperture ratio AR and the width Ws of the metal line.

However, in the above-described respective relational expressions, the unit of each of Ws, Ps, W1, P1, W2, and P2 is micrometer. In the embodiment, when the width W1 of each first extension part 21 differs (e.g., due to a design error and the like), an average of the widths W1 of a plurality of adjacent first extension parts 21 is set to the W1 in each relational expression described above. When the pitch P1 of each first extension part 21 differs, an average of the pitches P1 of the plurality of adjacent first extension parts 21 is set to P1 in each relational expression described above. When the width W2 of each second extension part 22 differs, an average of the widths W2 of the plurality of adjacent second extension parts 22 is set to W2 in each relational expression described above. When the pitch P2 of each second extension part 22 differs, an average of the pitches P2 of the plurality of adjacent second extension parts 22 is set to P2 in each relational expression described above.

Next, the inventors conducted experiments on each sample to see whether or not a transmission image blurs, using the same plurality of samples as in the above-described experiment. In the experiment, the sample was disposed between an object to be observed and the examinee. The object to be observed, the sample, and the examinee are substantially linearly arranged. The examinee was caused to face substantially straight a surface, in which the metal pattern is provided, of the sample. As the object to be observed, letters “ABC” were used. The distance L1 between the sample and the examinee was set to 1 m. In the experiment, for each sample, a distance L2 between the object to be observed and the sample was varied, and the evaluation was conducted at a plurality of distances L2. Specifically, the distance L2 was varied to 0.6 m, 1.2 m or 10 m, and the evaluation was conducted. In the experiment, there is one examinee. The examinee's eyesight is 1.5. Because blurring of a transmission image is not related to the eyesight, hereinafter the correction based on the eyesight was not performed unlike the above-described experiments on the visibility of the metal line.

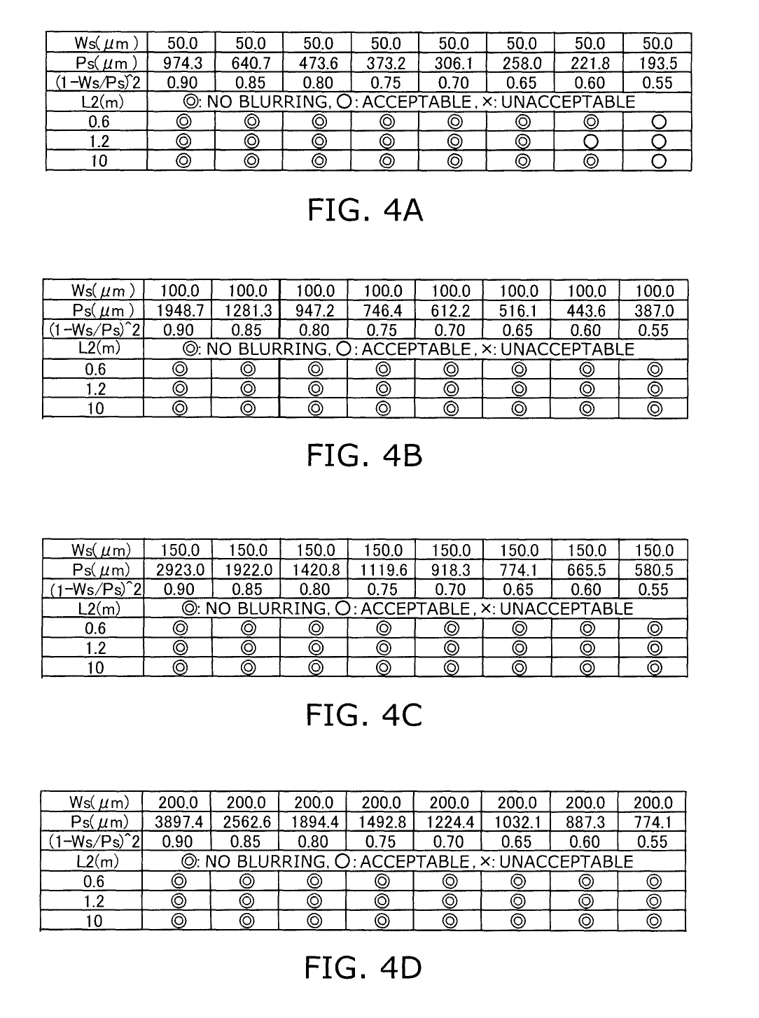

FIGS. 4A to 4D are the tables showing an example of the experimental results.

FIG. 4A shows the evaluation results of each sample in which the width Ws of the metal line was set to 50 μm. FIG. 4B shows the evaluation results of each sample in which the width Ws of the metal line was set to 100 μm. FIG. 4C shows the evaluation result of each sample in which the width Ws of the metal line was set to 150 μm. FIG. 4D shows the evaluation result of each sample in which the width Ws of the metal line was set to 200 μm.

In FIGS. 4A to 4D, a sample, in which the blurring of a transmission image (unevenness in a transmission image) was not annoying (blurring has not been recognized), is marked with “OO”, a sample, in which the blurring of a transmission image was recognized to an acceptable extent, is marked with “O”, and a sample, in which the blurring of a transmission image is unacceptable, is marked with “X”.

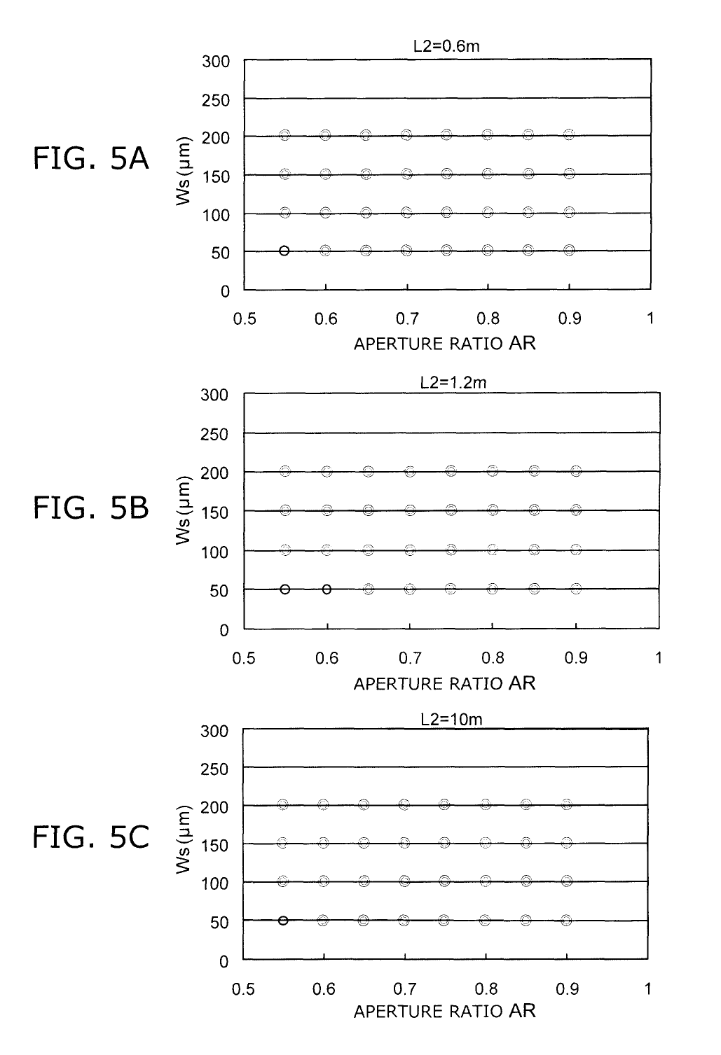

FIGS. 5A to 5C are graphs showing an example of the experimental results.

FIG. 5A is a graph summarizing the experimental results at the distance L2=0.6 m.

FIG. 5B is a graph summarizing the experimental results at the distance L2=1.2 m.

FIG. 5C is a graph summarizing the experimental results at the distance L2=10 m.

As shown in FIGS. 5A to 5C, the inventors have found, by the experiment, that an unacceptable level of blurring of a transmission image does not occur when the metal pattern has a grid pattern shape. That is, the inventors have found, by the experiment, that the blurring of a transmission image can be suppressed by forming the second electrode 20 in a grid pattern.

In the organic electroluminescent device 110 according to the embodiment, in the grid-shaped second electrode 20, the width W1 and pitch P1 of each first extension part 21 satisfy the relationship of W1≦−750(1−W1/P1)(1−W2/P2)+675 while the width W2 and pitch P2 of each second extension part 22 satisfy the relationship of W2≦−750(1−W1/P1)(1−W2/P2)+675. Alternatively, when the width W1 differs from the width W2, they satisfy the relationship of max(W1, W2)≦−750×(1−max(W1/P1, W2/P2))²+675. As a result, in the second electrode 20, each first extension part 21 and each second extension part 22 can be made invisible. The blurring of a transmission image can be suppressed. Accordingly, the visibility of a transmission image can be improved.

The width W1 of each first extension part 21 and the pitch P1 of each first extension part 21 do not necessarily need to be the same in the respective first extension parts 21. The width W1 and pitch P1 of each first extension part 21 may differ as long as they satisfy the above-described relationships. The width W2 of each second extension part 22 and the pitch P2 of each second extension part 22 do not necessarily need to be the same in the respective second extension parts 22. The width W2 and pitch P2 of each second extension part 22 may differ as long as they satisfy the above-described relationships.

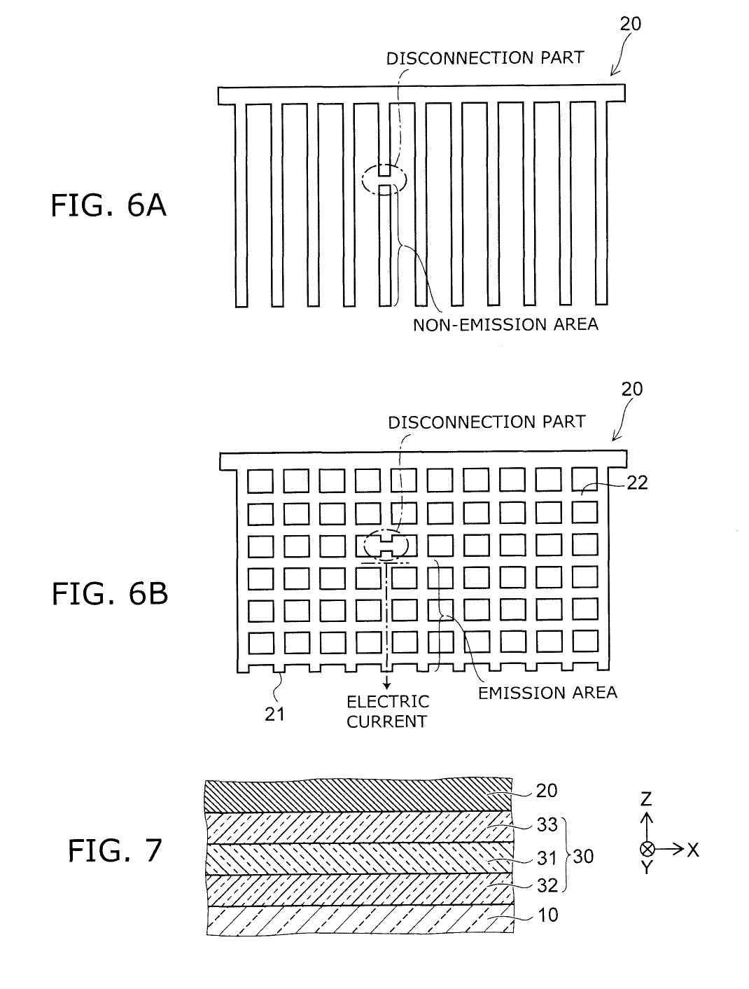

FIGS. 6A and 6B are schematic plan views showing an example of the second electrode.

As shown in FIG. 6A, in a stripe pattern-shaped second electrode 20, when a part of the extension part has a disconnection, the portion ahead of this disconnection portion results in a non-emission area.

On the other hand, as shown in FIG. 6B, in a grid pattern shaped second electrode 20, also when a part of the first extension part 21 or a part of the second extension part 22 has a disconnection, electric current can be fed from the adjacent first extension part 21 or adjacent second extension part 22 also to the portion ahead of the disconnection part. That is, the portion ahead of the disconnection part can serve also as the emission area.

As described above, in the grid-shaped second electrode 20, the generation of a non-emission area due to disconnection can be also suppressed as compared with the striped second electrode 20. For example, the reliability of the organic electroluminescent device 110 can be improved.

FIG. 7 is a schematic cross-sectional view showing a part of the organic electroluminescent device according to the first embodiment.

As shown in FIG. 7, the organic light-emitting layer 30 includes a first layer 31. The organic light-emitting layer 30 can further include at least any one of a second layer 32 and a third layer 33, as required. The first layer 31 emits light having a wavelength of visible light. The second layer 32 is provided between the first layer 31 and the first electrode 10. The third layer 33 is provided between the first layer 31 and the second electrode 20.

For the first layer 31, the materials, such as Alq₃ (tris(8-hydroxyquinolinolato)aluminum), F8BT (poly(9,9-dioctylfluorene-co-benzothiadiazole) and PPV (polyparaphenylene-vinylene), can be used, for example. For the first layer 31, a mixed material of a host material and a dopant added into the host material can be used. As the host material, for example CBP (4,4′-N,N′-bisdicarbazolyl-biphenyl), BCP (2,9-dimethyl-4,7-diphenyl-1,10-phenanthroline), TPD (4,4′-bis-N-3-methylphenyl-N-phenylaminobiphenyl), PVK(polyvinylcarbazole), PPT (poly(3-phenylthiophene)), or the like can be used. As the dopant material, for example Flrpic (iridium(III)bis(4,6-di-fluorophenyl)-pyridinate-N,C2′-picolinate), Ir(ppy)₃ (tris(2-phenylpyridine)iridium), FIr6 (bis(2,4-difluorophenylpyridinate)-tetrakis(1-pyrazolyl)borate-iridium(III)), or the like can be used. The material of the first layer 31 is not limited to the above-described materials. The material of the first layer is not limited to these materials.

The second layer 32 functions as a hole injection layer, for example. The hole injection layer contains at least any one of PEDPOT: PPS (poly(3,4-ethylenedioxythiophene)-poly(styrenesulfonicacid)), CuPc (copper phthalocyanine), MoO₃ (molybdenum trioxide), and the like, for example. The second layer 32 functions as a hole transport layer, for example. The hole transport layer contains at least any one of, for example, α-NPD (4,4′-bis[N-(1-naphthyl)-N-phenylamino]biphenyl), TAPC (1,1-bis[4-[N,N-di(p-tolyl)amino]phenyl]cyclohexane), m-MTDATA (4,4′,4″-tris[phenyl(m-tolyl)amino]triphenylamine), TPD (bis(3-methylphenyl)-N,N′-diphenylbenzidine), TCTA (4,4′,4″-tri(N-carbazolyl)triphenylamine), and the like, for example. The second layer 32 may include, for example, a stacked structure of a layer functioning as the hole injection layer and a layer functioning as the hole transport layer. The second layer 32 may include a layer different from the layer functioning as the hole injection layer and from the layer functioning as the hole transport layer. The material of the second layer is not limited to these materials.

The third layer 33 can include, for example, a layer functioning as an electron injection layer. The electron injection layer contains, for example, at least any one of lithium fluoride, cesium fluoride, lithium quinoline complex, and the like. The third layer 33 can include, for example, a layer functioning as an electron transportation layer. The electron transportation layer contains, for example, at least any one of Alq3 (tris(8 quinolinolato)aluminum(III)), BAlq (bis(2-methyl-8-quinolilate)(p-phenylphenolate)aluminum), Bphen(bathophenanthroline), 3TPYMB (tris[3-(3-pyridyl)-mesityl]borane), and the like. The third layer 33 may include, for example, a stacked structure of a layer functioning as the electron injection layer and a layer functioning as the electron transportation layer. The third layer 33 may include a layer different from a layer functioning as the electron injection layer and from a layer functioning as the electron transportation layer. The material of the third layer 33 is not limited to these materials.

For example, the light emitted from the organic light-emitting layer 30 is substantially white light. That is, the light emitted from the organic electroluminescent device 110 is white light. Here, the “white light” is substantially white, and includes, for example, reddish, yellowish, greenish, bluish, and/or purplish white light, as well.

The first electrode 10 includes an oxide that contains at least any one element selected from the group consisted of In, Sn, Zn, and Ti, for example. For the first electrode 10, for example a film (e.g., NESA or the like) fabricated using a conductive glass containing, indium oxide, zinc oxide, tin oxide, indium tin oxide (ITO), fluorine-doped tin oxide (FTO), or indium zinc oxide, and gold, platinum, silver, copper, or the like can be used. The first electrode 10 functions as an anode, for example. The material of the first electrode 10 is not limited to these materials.

The second electrode 20 contains at least any one of aluminum and silver, for example. For example, an aluminum film is used for the second electrode 20. Furthermore, an alloy of silver and magnesium may be used for the second electrode 20. Calcium may be added into this alloy. The second electrode 20 functions as a cathode, for example. The material of the second electrode 20 is not limited to these materials.

Alternatively, the first electrode 10 may have a stacked structure of a light reflective electrode and a light transmissive electrode (e.g., transparent electrode), and may be patterned in a grid pattern, while the second electrode 20 may be a light transmissive electrode (e.g., transparent electrode). As a result, the organic electroluminescent device 110 of a top emission type can be formed.

The first electrode 10 may be set to the cathode and the second electrode 20 may be to the anode, so that the second layer 32 may be caused to function as the electron injection layer or electron transportation layer and the third layer 33 may be caused to function as the hole injection layer or hole transport layer.

The thickness (the length in the Z-axis direction) of the first electrode 10 is not less than 10 nm and not more than 500 nm, for example, and more preferably, not less than 50 nm and not more than 200 nm. The thickness of the organic light-emitting layer 30 is not less than 50 nm and not more than 500 nm, for example. The thickness of the second electrode 20 (the first extension part 21 and the second extension part 22) is not less than 10 nm and not more than 300 nm, for example. The width W1 (the length in the X-axis direction) of the first extension part 21 is not less than 1 μm and not more than 500 μm, for example. The pitch P1 of each first extension part 21 is not less than 2 μm and not more than 2000 μm, for example, and more preferably, not less than 2 μm and not more than 200 μm. The width W2 (the length in the Y-axis direction) of the second extension part 22 is not less than 1 μm and not more than 500 μm, for example. The pitch P2 of each second extension part 22 is not less than 2 μm and not more than 2000 μm, for example, and more preferably, not less than 2 μm and not more than 200 μm.

In the above-described numerical value ranges, the width W1 and pitch P1 of each first extension part 21 are set to satisfy the relationship of W1≦−750(1−W1/P1)(1−W2/P2)+675, and the width W2 and pitch P2 of each second extension part 22 are set to satisfy the relationship of W2≦−750(1−W1/P1)(1−W2/P2)+675. Alternatively, when the width W1 differs from the width W2, they satisfy the relationship of max(W1, W2)≦−750×(1−max(W1/P1, W2/P2))²+675. As a result, a high visibility of a transmission image can be obtained.

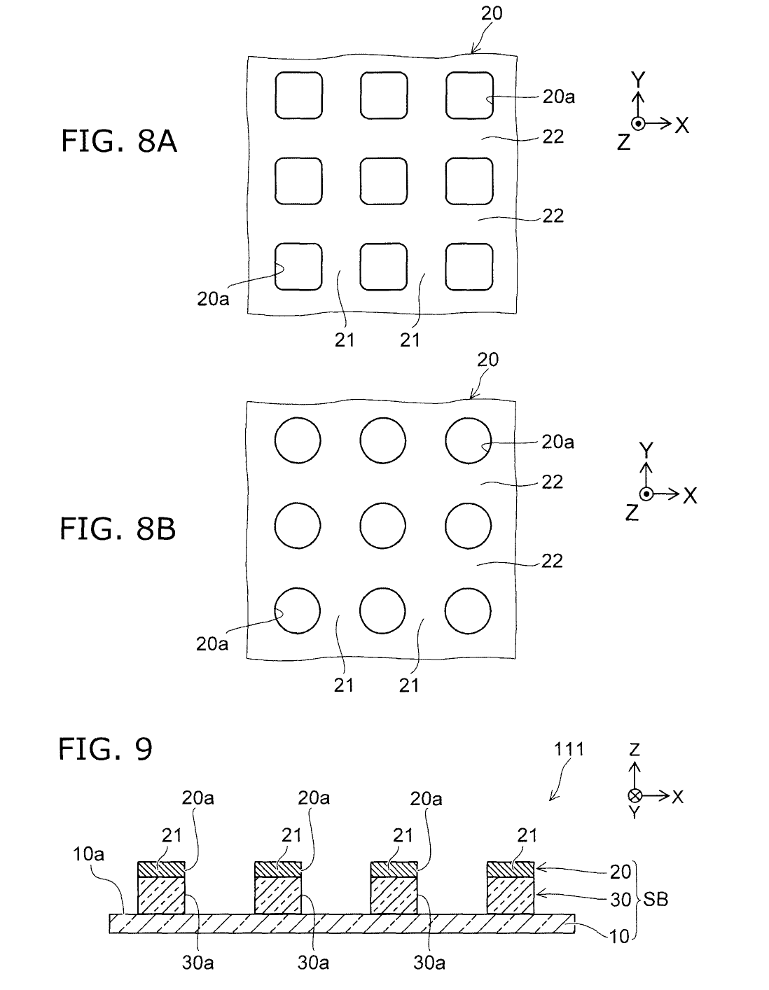

FIGS. 8A and 8B are schematic plan views showing a part of another organic electroluminescent device according to the first embodiment.

As shown in FIG. 8A, the shape of the opening 20a of the second electrode 20, projected onto the X-Y plane may be a rectangular shape whose vertex portions are rounded.

As shown in FIG. 8B, the shape of the opening 20a, projected onto the X-Y plane may be circular.

As described above, the shape of the opening 20a is not limited to the rectangular shape, but may be a circular shape, elliptic shape, or other polygonal shape. In a polygonal shape, the vertex portions may have a rounded shape. In the specification, the “grid shape” includes a grid shape whose opening is rectangular and a grid shape whose opening has any shape. For example, the “grid shape” includes a honeycomb shape and the like. That is, the pattern shape of the second electrode 20 may be a honeycomb shape or the like. The second electrode 20 may include a plurality of parts extending in the Y-axis direction and arranged in the X-axis direction, and a plurality of parts extending in the X-axis direction and arranged in the Y-axis direction. The first extension part 21 and the second extension part 22 do not necessarily need to be linear, but may be curved or bent in a zigzag shape. That is, the first extension part 21 may include a component extending in the Y-axis direction. The second extension part 22 may include a component extending in the X-axis direction.

FIG. 9 is a schematic cross-sectional view showing another organic electroluminescent device according to the first embodiment.

As shown in FIG. 9, in an organic electroluminescent device 111, the organic light-emitting layer 30 includes a plurality of openings 30a. Each of the plurality of openings 30a (the second openings) is disposed, for example, at a location where it overlaps with each of the plurality of openings 20a (the first openings) of the second electrode 20 when it is projected onto the X-Y plane. The opening 30a exposes a part of the first electrode 10, for example. That is, in the organic electroluminescent device 111, the organic light-emitting layer 30 is patterned in a grid pattern shape similar to the second electrode 20. As described above, the organic light-emitting layer 30 does not necessarily need to be provided on the whole first electrode 10. The organic light-emitting layer 30 may include at least a portion provided between the first electrode and the second electrode 20. That is, the organic light-emitting layer 30 may include at least a portion serving as the emission area EA.

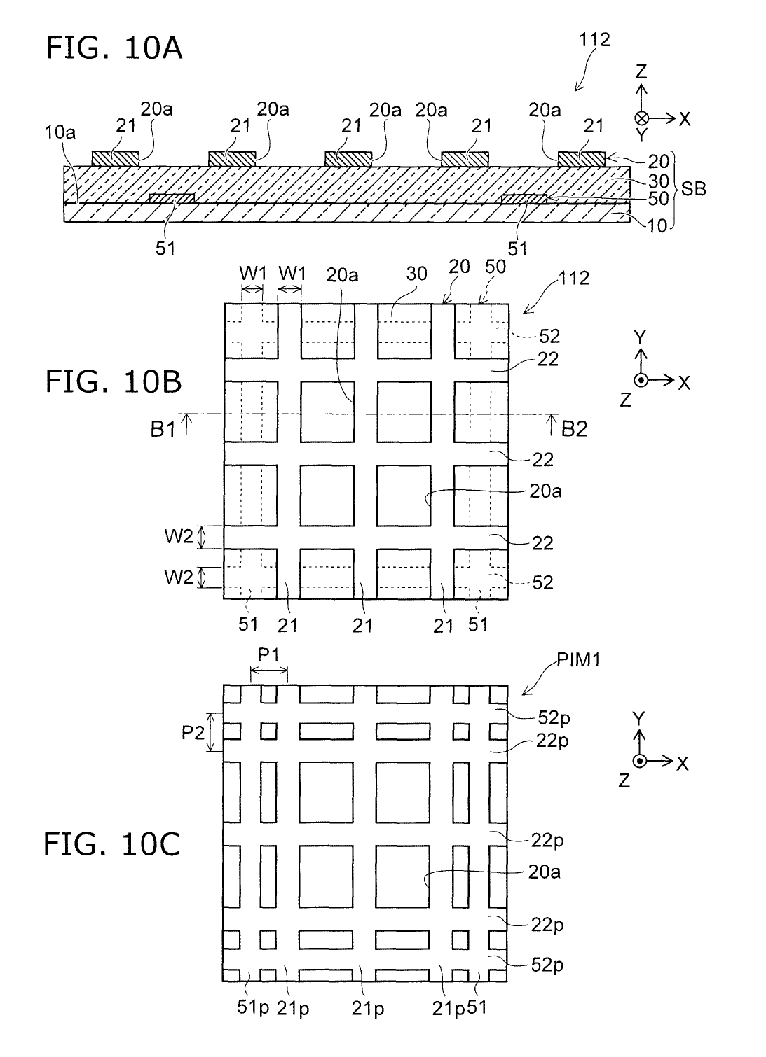

FIGS. 10A to 10C are schematic views showing another organic electroluminescent device according to the first embodiment.

FIG. 10A is a schematic cross-sectional view of an organic electroluminescent device 112, and FIG. 10B is a schematic plan view of the organic electroluminescent device 112. FIG. 10A schematically shows the cross-section along a B1-B2 line of FIG. 10B. FIG. 10C shows a projection image PIM1 when a part of the organic electroluminescent device 112 is projected onto the X-Y plane.

As shown in FIGS. 10A to 10C, the stacked body SB of the organic electroluminescent device 112 further includes a wiring layer 50.

The wiring layer 50 extends along a plane parallel to the upper face 10a. That is, the wiring layer 50 extends in the X-Y plane. In this example, the wiring layer 50 is provided on the upper face 10a of the first electrode 10. The wiring layer 50 is provided between the first electrode 10 and the organic light-emitting layer 30, for example. The wiring layer 50 may be provided on the surface opposite the upper face 10a of the first electrode 10.

The wiring layer 50 includes a plurality of first wiring parts 51 and a plurality of second wiring parts 52. Each of the plurality of first wiring parts 51 extends in the Y-axis direction and is arranged in the X-axis direction. Each of the plurality of second wiring parts 52 extends in the X-axis direction, is arranged in the Y-axis direction, and intersects with each of the plurality of first wiring parts 51.

Each first wiring part 51 is disposed, for example, at a location where it does not overlap with each first extension part 21 when it is projected onto the X-Y plane. Each first wiring part 51 may be disposed at a location where it overlaps with each first extension part 21 when it is projected onto the X-Y plane. The pitch of each first wiring part 51 differs from the pitch of each first extension part 21, for example. In this example, three first extension parts 21 are provided between each of the first wiring parts 51. The pitch of each first wiring part 51 may be substantially the same as the pitch of each first extension part 21. The pitch of each first wiring part 51 may be arbitrary.

Each second wiring part 52 is disposed, for example, at a location where it does not overlap with each second extension part 22 when it is projected onto the X-Y plane. Each second wiring part 52 may be disposed at a location where it overlaps with each second extension part 22 when it is projected onto the X-Y plane. The pitch of each second wiring part 52 differs from the pitch of each second extension part 22, for example. In this example, three second extension parts 22 are provided between each of the second wiring parts 52. The pitch of each second wiring part 52 may be substantially the same as the pitch of each second extension part 22. The pitch of each second wiring part 52 may be arbitrary.

The wiring layer 50 is electrically connected to the first electrode 10. The wiring layer 50 is in contact with the first electrode 10, for example. The electric conductivity of the wiring layer 50 is higher than the electric conductivity of the first electrode 10. The wiring layer 50 is light reflective. The light reflectance of the wiring layer 50 is higher than the light reflectance of the first electrode 10. The wiring layer 50 is metal wirings, for example. The wiring layer 50 functions as an auxiliary electrode that transmits the electric current flowing into the first electrode 10, for example. As a result, in the organic electroluminescent device 112, for example the amount of current flowing in the direction perpendicular to the upper face 10a of the first electrode 10 can be made uniform as compared with the organic electroluminescent device 110. For example, the in-plane emission luminance can be made more uniform.

As shown in FIG. 10C, in the organic electroluminescent device 112, the projection image PIM1 when the second electrode 20 and the wiring layer 50 are projected onto the X-Y plane includes a plurality of projection images 21p of the respective plurality of first extension parts 21, a plurality of projection images 22p of the respective plurality of second extension parts 22, a plurality of projection images 51p of the respective plurality of first wiring parts 51, and a plurality of projection images 52p of the respective plurality of second wiring parts 52. That is, the projection image PIM1 has the shape of the light reflective part of the organic electroluminescent device 112.

In this example, the width W1 includes the width of each first wiring part 51. That is, in this example, the width W1 is the length in the X-axis direction of each of the plurality of first extension parts 21 and is the length in the X-axis direction of each of the plurality of first wiring parts 51.

In this example, the width W2 includes the width of each second wiring part 52. That is, in this example, the width W2 is the length in the Y-axis direction of each of the plurality of second extension parts 22 and is the length in the Y-axis direction of each of the plurality of second wiring parts 52.

In this example, the pitch P1 is the pitch of each of the respective projection images 21p of the plurality of first extension parts 21 and each of the respective projection images 51p of the plurality of first wiring parts 51. The pitch P1 may be the minimum distance in the X-axis direction between a center in the X-axis direction of the projection image 21p of the first extension part 21 and a center in the X-axis direction of the projection image 51p of the first wiring part 51, for example. That is, the pitch P1 may be the center-to-center distance in the X-axis direction between the projection image 21p and the projection image 51p closest to the projection image 21p, for example.

In this example, the pitch P2 is the pitch of each of the respective projection images 22p of the plurality of second extension parts 22 and each of the respective projection images 52p of the plurality of second wiring parts 52. The pitch P2 may be the minimum distance in the X-axis direction between a center in the Y-axis direction of the projection image 22p of the second extension part 22 and a center in the X-axis direction of the projection image 52p of the second wiring part 52, for example. That is, the pitch P2 may be the center-to-center distance in the Y-axis direction between the projection image 22p and the projection image 52p closest to the projection image 22p, for example.

In this example, each of the plurality of first extension parts 21 and each of the plurality of first wiring parts 51 satisfy the relationship of W1≦−750(1−W1/P1)(1−W2/P2)+675. Then, each of the plurality of second extension parts 22 and each of the plurality of second wiring parts 52 satisfy the relationship of W2≦−750(1−W1/P1)(1−W2/P2)+675. That is, the light reflective part of the organic electroluminescent device 112 satisfies the relationship between the width and the pitch described in the organic electroluminescent device 110. Alternatively, when the width W1 differs from the width W2, they satisfy the relationship of max(W1, W2)≦−750×(1−max(W1/P1, W2/P2))²+675.

As a result, also in the organic electroluminescent device 112, a high visibility of a transmission image can be obtained. Also in the above-described relational expression, the unit of each of W1, W2, P1, and P2 is micrometer.

The wiring layer 50 contains at least any one element selected from the group consisted of Mo, Ta, Nb, Al, Ni and Ti, for example. The wiring layer 50 can be a mixed film containing the elements selected from this group, for example. The wiring layer 50 can be a stacked film containing these elements. For the wiring layer 50, a stacked film of Nb/Mo/Al/Mo/Nb can be used, for example. The wiring layer 50 functions as an auxiliary electrode for suppressing a drop in the potential of the first electrode 10, for example. The wiring layer 50 can function as a lead electrode for supplying electric current. The material of the wiring layer 50 is not limited to these materials.

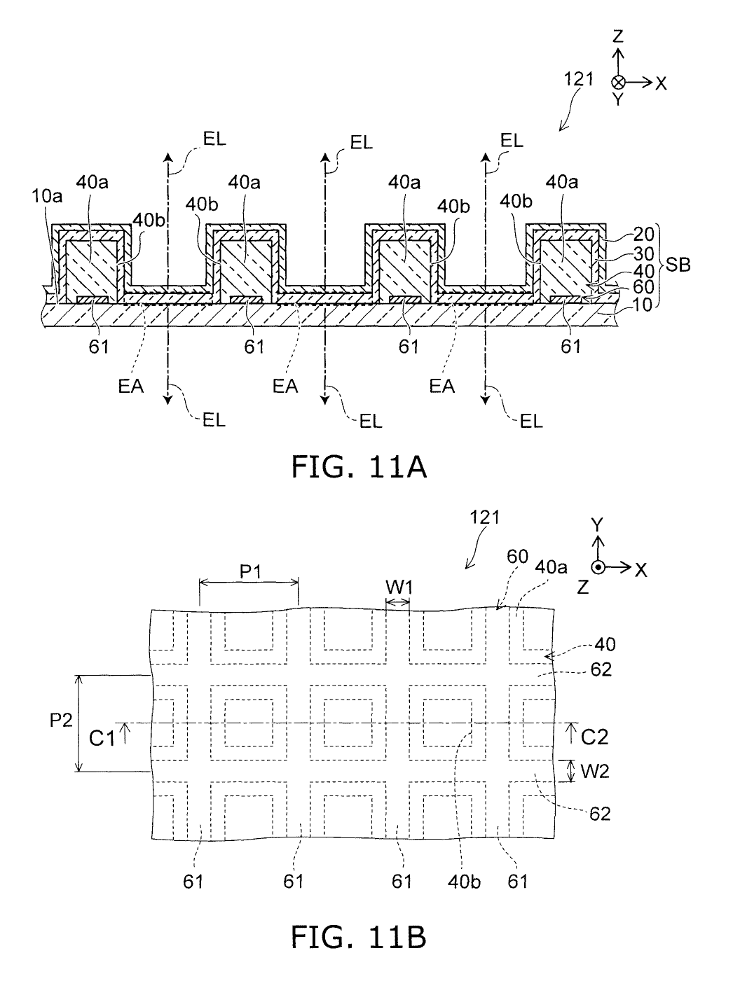

FIGS. 11A and 11B are schematic views showing another organic electroluminescent device according to the first embodiment.

FIG. 11A is a schematic cross-sectional view of an organic electroluminescent device 121, while FIG. 11B is a schematic plan view of the organic electroluminescent device 121. FIG. 11A shows the cross-section along a C1-C2 line of FIG. 11B.

As shown in FIGS. 11A and 11B, in the organic electroluminescent device 121, the second electrode 20 is provided on the organic light-emitting layer 30. For example, the second electrode 20 is provided on the whole organic light-emitting layer 30. In this example, the second electrode is light transmissive. The second electrode 20 is transparent, for example.

As a result, in the organic electroluminescent device 121, when electric current is fed into the organic light-emitting layer 30 using the first electrode 10 and the second electrode 20, the electroluminescence EL emitted from the emission area EA is emitted to the outside of the organic electroluminescent device 121 through the first electrode 10 and is also emitted to the outside of the organic electroluminescent device 121 through the second electrode 20. That is, the organic electroluminescent device 121 is of a double-sided electroluminescence type.

In the organic electroluminescent device 121, the stacked body SB further includes an insulating layer 40 and a first wiring layer 60.

The insulating layer 40 is light transmissive. The insulating layer 40 is transparent, for example. The insulating layer 40 is provided between the first electrode 10 and the organic light-emitting layer 30, for example. The insulating layer 40 includes an insulating part 40a and a plurality of openings 40b, for example. Each of the plurality of openings 40b is disposed side by side in a two-dimensional matrix in the X-axis direction and in the Y-axis direction. In this example, the pattern shape of the insulating layer 40 is grid-shaped. The thickness of the insulating layer 40 is not less than 1 μm and not more than 100 μm, for example.

Each of the plurality of openings 40b exposes a part of the first electrode 10. The organic light-emitting layer 30 is electrically connected to a portion exposed to each of the openings 40b in the first electrode 10. That is, in this example, a portion between the portion exposed to the opening 40b of the first electrode 10 in the organic light-emitting layers 30 and the second electrode 20 serves as the emission area EA.

The first wiring layer 60 is provided between the first electrode 10 and the insulating layer 40. The first wiring layer 60 includes a plurality of first wiring parts 61 and a plurality of second wiring parts 62. Each of the plurality of first wiring parts 61 extends in the Y-axis direction and is arranged in the X-axis direction. Each of the plurality of second wiring parts 62 extends in the X-axis direction, is arranged in the Y-axis direction, and intersects with each of the plurality of first wiring parts 61.

The first wiring layer 60 is electrically connected to the first electrode 10. The electric conductivity of the first wiring layer 60 is higher than the electric conductivity of the first electrode 10. The first wiring layer 60 functions as an auxiliary electrode for transmitting the electric current flowing into the first electrode 10, as with the wiring layer 50 described with respect to the organic electroluminescent device 112.

In this example, the length in the X-axis direction of each of the plurality of first wiring parts 61 is set to W1 (micrometer). The pitch of each of the plurality of first wiring parts 61 is set to P1 (micrometer). The length in the Y-axis direction of each of the plurality of second wiring parts 62 is set to W2 (micrometer). The pitch of each of the plurality of second wiring parts 62 is set to P2 (micrometer).

In the organic electroluminescent device 121, the width W1 and pitch P1 satisfy the relationship of W1≦−750(1−W1/P1)(1−W2/P2)+675. The width W2 and pitch P2 satisfy the relationship of W2≦−750(1−W1/P1)(1−W2/P2)+675. Alternatively, when the width W1 differs from the width W2, they satisfy the relationship of max(W1, W2)≦−750×(1−max(W1/P1, W2/P2))²+675.

As a result, also in the organic electroluminescent device 121, a high visibility of a transmission image can be obtained.

For the light transmissive second electrode 20, the material described about the first electrode 10 can be used, for example. Moreover, for the light transmissive second electrode 20, a metal material, such as MgAg, may be used, for example. In the metal material, the thickness of the second electrode 20 is set to not less than 5 nm and not more than 20 nm, for example. As a result, an appropriate light transmissivity can be obtained. The material of the light transmissive second electrode 20 is not limited to these materials.

An insulating resin material, such as a polyimide resin or an acrylic resin, or an insulating inorganic material, such as a silicone oxide film (e.g., SiO₂), a silicon nitride film (e.g., SiN), or a silicon oxynitride film, is used for the insulating layer 40, for example. The material of the insulating layer 40 is not limited to these materials.

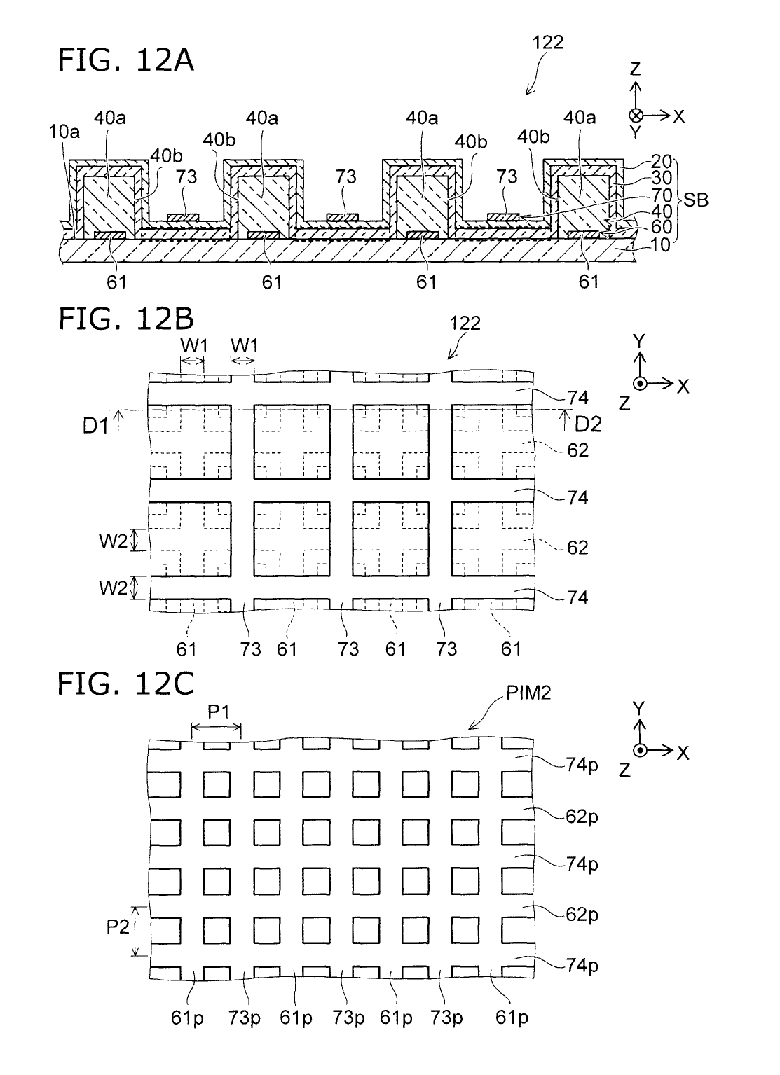

FIGS. 12A to 12C are schematic views showing another organic electroluminescent device according to the first embodiment.

FIG. 12A is a schematic cross-sectional view of an organic electroluminescent device 122. FIG. 12B is a schematic plan view of the organic electroluminescent device 122. FIG. 12A shows the cross-section along a D1-D2 line of FIG. 12B.

FIG. 12C shows a projection image PIM2 when a part of the organic electroluminescent device 122 is projected onto the X-Y plane.

As shown in FIGS. 12A to 12C, the stacked body SB of the organic electroluminescent device 122 further includes a second wiring layer 70.

The second wiring layer 70 is provided on the second electrode 20. The second wiring layer 70 includes a plurality of third wiring parts 73 and a plurality of fourth wiring parts 74. Each of the plurality of third wiring parts 73 extends in the Y-axis direction and is arranged in the X-axis direction. Each of the plurality of fourth wiring parts 74 extends in the X-axis direction, is arranged in the Y-axis direction, and intersects with each of the plurality of third wiring parts 73. In this example, the pattern shape of the second wiring layer 70 is grid-shaped.

In this example, each of the plurality of third wiring parts 73 is disposed at a location where it does not overlap with each of the plurality of first wiring parts 61 when it is projected onto the X-Y plane. Each of the plurality of third wiring parts 73 may be disposed at a location where it overlaps with each of the plurality of first wiring parts 61 when it is projected onto the X-Y plane, for example.

In this example, each of the plurality of fourth wiring parts 74 is disposed at a location where it does not overlap with each of the plurality of second wiring parts 62 when it is projected onto the X-Y plane. Each of the plurality of fourth wiring parts 74 may be disposed at a location where it overlaps with each of the plurality of second wiring parts 62 when it is projected onto the X-Y plane, for example.

The second wiring layer 70 is electrically connected to the second electrode 20. The second wiring layer 70 is in contact with the second electrode 20, for example. The electric conductivity of the second wiring layer 70 is higher than the electric conductivity of the second electrode 20. The second wiring layer 70 is light reflective. The light reflectance of the second wiring layer 70 is higher than the light reflectance of the second electrode 20. The second wiring layer 70 is metal wirings, for example. The second wiring layer 70 functions as an auxiliary electrode for transmitting the electric current flowing into the second electrode 20, for example. As a result, in the organic electroluminescent device 122, for example the amount of current flowing in the Z-axis direction of the second electrode 20 can be made more uniform. For example, the in-plane emission luminance can be made more uniform.

As shown in FIG. 12C, in the organic electroluminescent device 122, the projection image PIM2 when the first wiring layer 60 and the second wiring layer 70 are projected onto the X-Y plane includes a plurality of projection images 61p, a plurality of projection images 62p, a plurality of projection images 73p, and a plurality of projection images 74p. Each projection image 61p is the projection image of each first wiring part 61. Each projection image 62p is the projection image of each second wiring part 62. Each projection image 73p is the projection image of each third wiring part 73. Each projection image 74p is the projection image of each fourth wiring part 74.

In this example, the length in the X-axis direction of each of the plurality of first wiring parts 61 and the length in the X-axis direction of each of the plurality of third wiring parts 73 are set to the width W1 (micrometer). The length in the Y-axis direction of each of the plurality of second wiring parts 62 and the length in the Y-axis direction of each of the plurality of fourth wiring parts 74 are set to the width W2 (micrometer). The pitch of each of the plurality of projection images 61p and plurality of projection images 73p is set to the pitch P1 (micrometer). The pitch of each of the plurality of projection images 62p and plurality of projection images 74p is set to the pitch P2 (micrometer).

The pitch P1 may be the minimum distance in the X-axis direction between a center in the X-axis direction of the projection image 61p of the first wiring part 61 and a center in the X-axis direction of the projection image 73p of the third wiring part 73, for example. That is, the pitch P1 may be the center-to-center distance in the X-axis direction between the projection image 61p and the projection image 73p closest to the projection image 61p, for example.

The pitch P2 may be the minimum distance in the Y-axis direction between a center in the Y-axis direction of the projection image 62p of the second wiring part 62 and a center in the Y-axis direction of the projection image 74p of the fourth wiring part 74, for example. That is, the pitch P2 may be the center-to-center distance in the Y-axis direction between the projection image 62p and the projection image 74p closest to the projection image 62p, for example.

In the organic electroluminescent device 122, each of the plurality of first wiring parts 61 and each of the plurality of third wiring parts 73 satisfy the relationship of W1≦−750(1−W1/P1)(1−W2/P2)+675. Each of the plurality of second wiring parts 62 and each of the plurality of fourth wiring parts 74 satisfy the relationship of W2≦−750(1−W1/P1)(1−W2/P2)+675. Alternatively, when the width W1 differs from the width W2, they satisfy the relationship of max(W1, W2)≦−750×(1−max(W1/P1, W2/P2))²+675.

As a result, also in the organic electroluminescent device 122, a high visibility of a transmission image can be obtained. For the first wiring layer 60 and the second wiring layer 70, substantially the same material as the material described about the wiring layer 50 can be used, for example.

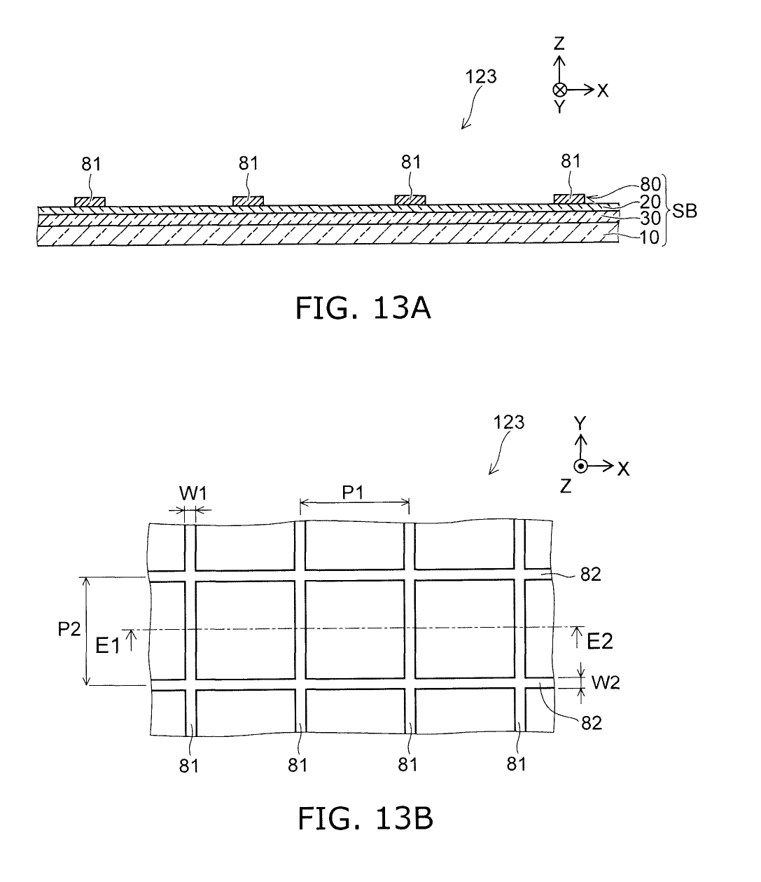

FIGS. 13A and 13B are schematic views showing another organic electroluminescent device according to the first embodiment.

FIG. 13A is a schematic cross-sectional view of an organic electroluminescent device 123, and FIG. 13B is a schematic plan view of the organic electroluminescent device 123. FIG. 13A shows the cross-section along an E1-E2 line of FIG. 13B.

As shown in FIGS. 13A and 13B, in the organic electroluminescent device 123, the stacked body SB further includes a wiring layer 80. The wiring layer 80 is provided on the second electrode 20. The wiring layer 80 includes a plurality of first wiring parts 81 and a plurality of second wiring parts 82. Each of the plurality of first wiring parts 81 extends in the Y-axis direction and is arranged in the X-axis direction. Each of the plurality of second wiring parts 82 extends in the X-axis direction, is arranged in the Y-axis direction, and intersects with each of the plurality of first wiring parts 81. In this example, the pattern shape of the wiring layer 80 is grid-shaped.

The wiring layer 80 is electrically connected to the second electrode 20. The electric conductivity of the wiring layer 80 is higher than the electric conductivity of the second electrode 20. The wiring layer 80 functions as an auxiliary electrode for transmitting the electric current flowing into the second electrode 20, as with the second wiring layer 70 described about the organic electroluminescent device 122.

In this example, the length in the X-axis direction of each of the plurality of first wiring parts 81 is set to W1 (micrometer). The pitch of each of the plurality of first wiring parts 81 is set to P1 (micrometer). The length in the Y-axis direction of each of the plurality of second wiring parts 82 is set to W2 (micrometer). The pitch of each of the plurality of second wiring parts 82 is set to P2 (micrometer).

In the organic electroluminescent device 123, the width W1 and pitch P1 satisfy the relationship of W1≦−750(1−W1/P1)(1−W2/P2)+675. The width W2 and pitch P2 satisfy the relationship of W2≦−750(1−W1/P1)(1−W2/P2)+675. Alternatively, when the width W1 differs from the width W2, they satisfy the relationship of max(W1, W2)≦−750×(1−max(W1/P1, W2/P2))²+675.

As a result, also in the organic electroluminescent device 123, a high visibility of a transmission image can be obtained. For the wiring layer 80, substantially the same material as the material described about the wiring layer 50 can be used, for example.

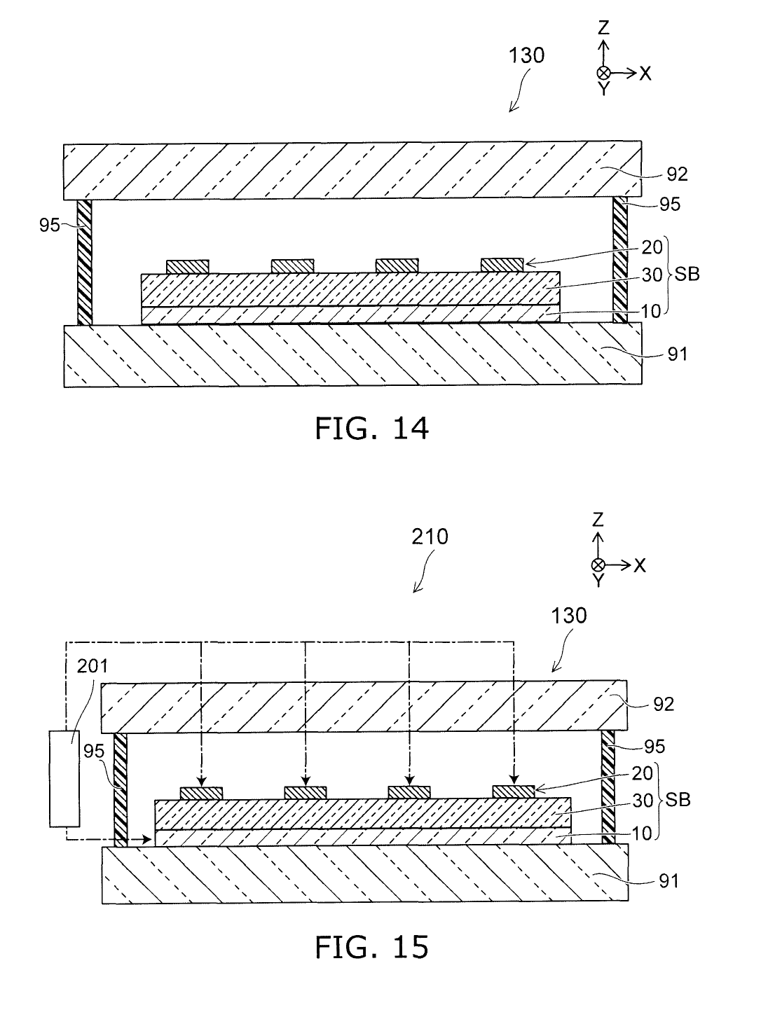

FIG. 14 is a schematic cross-sectional view showing another organic electroluminescent device according to the first embodiment.

As shown in FIG. 14, an organic electroluminescent device 130 further includes a first substrate 91, a second substrate 92, and a seal part 95.

The first electrode 10 is provided on the first substrate 91. The stacked body SB is provided on the first substrate 91. The first substrate 91 is light transmissive. The second substrate 92 is provided on the stacked body SB, and faces the first substrate 91. That is, the second substrate 92 is provided on the second electrode 20. The second substrate 92 is light transmissive. In this example, the configuration of the stacked body SB is the same as the configuration described with respect to the organic electroluminescent device 110. The configuration of the stacked body SB may be the configuration described about the organic electroluminescent devices 111 to 112 and 121 to 123.

The seal part 95 is annularly provided along the outer edges of the first substrate 91 and the second substrate 92, for example, and bonds the first substrate 91 and the second substrate 92. As a result, the stacked body SB is sealed by the first substrate 91 and the second substrate 92. In the organic electroluminescent device 130, the distance in the Z-axis direction between the first substrate 91 and the second substrate 92 is defined by the seal part 95. This configuration can be realized, for example, by including a granular spacer (the illustration is omitted) in the seal part 95. For example, a plurality of granular spacers are distributed in the seal part 95, so that the distance between the first substrate 91 and the second substrate 92 is defined by the diameters of the plurality of spacers.

In the organic electroluminescent device 130, the thickness (length along the Z-axis direction) of the seal part 95 is not less than 1 μm and not more than 100 μm, for example, and is more preferably, not less than 5 μm and not more than 20 μm, for example. As a result, for example, the infiltration of moisture and the like can be suppressed. The thickness of the seal part 95 is substantially the same as the diameter of the spacer distributed in the seal part 95, for example.

The organic electroluminescent device has a configuration of providing a recessed portion for housing the stacked body SB in the second substrate 92. This configuration makes the formation of the second substrate 92 difficult. For example, this configuration will increase the cost of the organic electroluminescent device.

In contrast, in the organic electroluminescent device 130 according to the embodiment, the distance between the first substrate 91 and the second substrate 92 is defined by the seal part 95. As a result, a tabular second substrate 92 can be used, for example. The second substrate 92 can be easily formed, for example. An increase in cost of the organic electroluminescent device 130 can be suppressed.

Inert gas or the like is filled in the space between the stacked body SB and the second substrate 92, for example. Drying agent or the like may be provided between the stacked body SB and the second substrate 92. The space between the stacked body SB and the second substrate 92 may be an air layer, for example. The degree of vacuum in the space between the stacked body SB and the second substrate 92 may be increased. A liquid acrylic resin, epoxy resin, or the like may be filled in the space between the stacked body SB and the second substrate 92, for example. Calcium oxide, barium oxide, or the like may be added into the acrylic resin or epoxy resin, as the drying agent.

For the first substrate 91 and the second substrate 92, a glass substrate, a resin substrate or the like is used, for example. For the seal part 95, an ultraviolet curing resin or the like is used, for example. In the stacked body SB, the second electrode 20 may be provided on the first substrate 91 so as to cause the organic light-emitting layer 30 to face the first substrate 91 through the second electrode 20.

### Second Embodiment

FIG. 15 is a schematic view showing an illumination apparatus according to a second embodiment.

As shown in FIG. 15, an illumination apparatus 210 according to the embodiment includes the organic electroluminescent device (e.g., organic electroluminescent device 130) according to the first embodiment, and a power source 201.

The power source 201 is electrically connected to the first electrode 10 and the second electrode 20. The power source 201 supplies electric current to the organic light-emitting layer 30 through the first electrode 10 and the second electrode 20.

The illumination apparatus 210 according to the embodiment can provide an illumination apparatus having high visibility of a transmission image.

### Third Embodiment

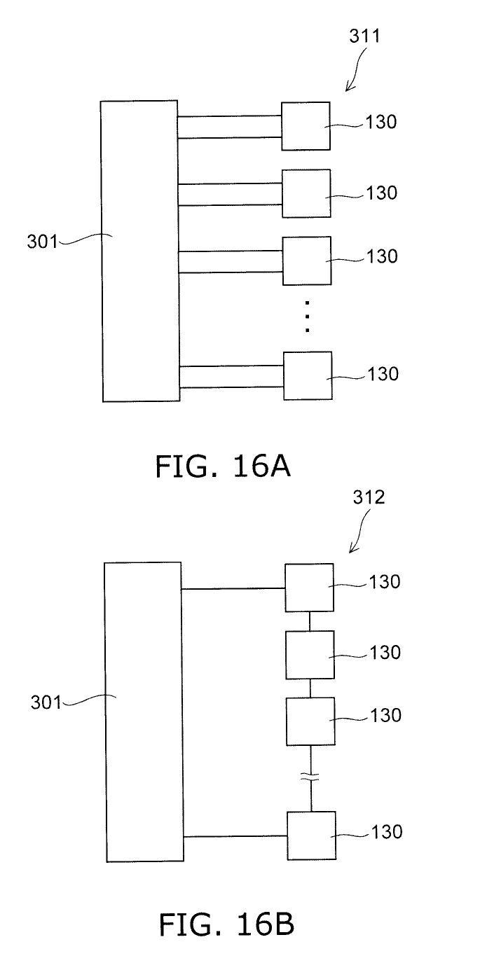

FIGS. 16A and 16B are schematic views showing an illumination system according to a third embodiment.

As shown in FIG. 16A, an illumination system 311 according to the embodiment includes a plurality of organic electroluminescent devices (e.g., organic electroluminescent devices 130) according to the first embodiment, and a controller 301.

The controller 301 is electrically connected to each of the plurality of organic electroluminescent devices 130, and controls turning on and turning off each of the plurality of organic electroluminescent devices 130. The controller 301 is electrically connected to the first electrode 10 and second electrode 20 of each of the plurality of organic electroluminescent devices 130, for example. As a result, the controller 301 individually controls turning on and turning off each of the plurality of organic electroluminescent devices 130.

As shown in FIG. 16B, in an illumination system 312, each of the plurality of organic electroluminescent devices 130 is connected in series. The controller 301 is electrically connected to the first electrode 10 of one organic electroluminescent device 130 of the plurality of organic electroluminescent devices 130. Then, the controller 301 is electrically connected to the second electrode 20 of another organic electroluminescent device 130 of the plurality of organic electroluminescent devices 130. As a result, the controller 301 collectively controls turning on and turning off each of the plurality of organic electroluminescent devices 130. As described above, the controller 301 may individually control turning on and turning off each of the plurality of organic electroluminescent devices 130, or may collectively control the plurality of organic electroluminescent devices 130.

The illumination systems 311 and 312 according to the embodiment can provide an illumination system having high visibility of a transmission image.

According to the embodiments, there are provided the organic electroluminescent device, illumination apparatus, and illumination system having high visibility of a transmission image.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the embodiments of the invention are not limited to these specific examples. For example, one skilled in the art may similarly practice the invention by appropriately selecting specific configurations of components included in organic electroluminescent devices, illumination apparatuses, and illumination systems such as first electrodes, second electrodes, organic light emitting layers, first wiring layers, second wiring layers, power sources, controllers, etc., from known art; and such practice is included in the scope of the invention to the extent that similar effects are obtained.

Further, any two or more components of the specific examples may be combined within the extent of technical feasibility and are included in the scope of the invention to the extent that the purport of the invention is included.

Moreover, all organic electroluminescent devices, illumination apparatuses, and illumination systems practicable by an appropriate design modification by one skilled in the art based on the organic electroluminescent devices, illumination apparatuses, and illumination systems described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An organic electroluminescent device, comprising:
a first electrode having an upper face, the first electrode being light transmissive;
an organic light-emitting layer provided on the upper face; and
a second electrode provided on the organic light-emitting layer, the second electrode being light reflective, the second electrode including a plurality of first extension parts and a plurality of second extension parts, the first extension parts extending in a first direction parallel to the upper face and being arranged in a second direction, the second direction being parallel to the upper face and intersecting with the first direction, the second extension parts extending in the second direction and being arranged in the first direction, the second extension parts intersecting with each of the first extension parts,
when a length of each of the first extension parts in the second direction is set to W1 (micrometer),
a pitch of each of the first extension parts is set to P1 (micrometer),
a length of each of the second extension parts in the first direction is set to W2 (micrometer), and
a pitch of each of the second extension parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.

2. The device according to claim 1, further comprising
a wiring layer provided between the first electrode and the organic light-emitting layer, the wiring layer being light reflective, the wiring layer including
a plurality of first wiring parts extending in the first direction and arranged in the second direction, and
a plurality of second wiring parts extending in the second direction and arranged in the first direction, the second wiring parts intersecting with each of the first wiring parts,
the W1 being the length in the second direction of each of the first extension parts and a length in the second direction of each of the first wiring parts,
the W2 being the length in the first direction of each of the second extension parts and a length in the first direction of each of the second wiring parts,
the P1 being a pitch of each of a projection image of each of the first extension parts and of a projection image of each of the first wiring parts when the first extension parts and the first wiring parts are projected onto a plane parallel to the upper face,
the P2 being a pitch of each of a projection image of each of the second extension parts and of a projection image of each of the second wiring parts when the second extension parts and the second wiring parts are projected onto the plane,
each of the first extension parts and each of the first wiring parts satisfying a relationship of W1≦−750(1−W1/P1)(1−W2/P2)+675, and
each of the second extension parts and each of the second wiring parts satisfying a relationship of W2≦−750(1−W1/P1)(1−W2/P2)+675.

3. The device according to claim 2, wherein
the wiring layer is electrically connected to the first electrode, and
an electric conductivity of the wiring layer is higher than an electric conductivity of the first electrode.

4. The device according to claim 1, wherein the organic light-emitting layer includes:
a first layer;
a second layer provided between the first layer and the first electrode; and
a third layer provided between the first layer and the second electrode.

5. The device according to claim 1, wherein
the second electrode includes a plurality of first openings arranged in the first direction and the second direction,
the organic light-emitting layer includes a plurality of second openings, and
each of the second openings overlaps each of the first openings when projected onto a plane parallel to the upper face.

6. The device according to claim 1, further comprising: a first substrate, a second substrate, and a seal part,
the first substrate being light transmissive,
the first electrode being provided on the first substrate,
the second substrate being provided on the second electrode, and
the seal part being annularly provided along outer edges of the first substrate and the second substrate, the seal part sealing the first electrode, the organic light-emitting layer, and the second electrode.

7. An organic electroluminescent device, comprising:
a first electrode having an upper face, the first electrode being light transmissive;
an organic light-emitting layer provided on the first electrode;
a second electrode provided on the organic light-emitting layer, the second electrode being light transmissive; and
a first wiring layer provided between the first electrode and the organic light-emitting layer, the first wiring layer being light reflective, the first wiring layer including
a plurality of first wiring parts extending in a first direction parallel to the upper face and being arranged in a second direction, the second direction being parallel to the upper face and intersecting with the first direction, and
a plurality of second wiring parts extending in the second direction and being arranged in the first direction, the second wiring parts intersecting with each of the first wiring parts, and
when a length of each of the first wiring parts in the second direction is set to W1 (micrometer),
a pitch of each of the first wiring parts is set to P1 (micrometer),
a length of each of the second wiring parts in the first direction is set to W2 (micrometer), and
a pitch of each of the second wiring parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.

8. The device according to claim 7, further comprising
a second wiring layer provided on the second electrode, the second wiring layer being light reflective, the second wiring layer including
a plurality of third wiring parts extending in the first direction and being arranged in the second direction, and
a plurality of fourth wiring parts extending in the second direction and being arranged in the first direction, the fourth wiring parts intersecting with each of the third wiring parts,
the W1 being the length of each of the first wiring parts in the second direction and being a length of each of the third wiring parts in the second direction,
the W2 being the length of each of the second wiring parts in the first direction and being a length of each of the fourth wiring parts in the first direction,
the P1 being a pitch of each of a projection image of each of the first wiring parts and of a projection image of each of the third wiring parts when the first wiring parts and the third wiring parts are projected onto a plane parallel to the upper face,
the P2 being a pitch of each of a projection image of each of the second wiring parts and of a projection image of each of the fourth wiring parts when the second wiring parts and the fourth wiring parts are projected onto the plane,
each of the first wiring parts and each of the third wiring parts satisfying a relationship of W1≦−750(1−W1/P1)(1−W2/P2)+675, and
each of the second wiring parts and each of the fourth wiring parts satisfying a relationship of W2≦−750(1−W1/P1)(1−W2/P2)+675.

9. The device according to claim 7, further comprising an insulating layer provided between the first electrode and the organic light-emitting layer, the insulating layer being light transmissive,
the insulating layer including a plurality of openings for exposing a part of the first electrode, and
the first wiring layer being provided between the first electrode and the insulating layer.

10. The device according to claim 9, wherein the openings are arranged in the first direction and the second direction.

11. An organic electroluminescent device, comprising:
a first electrode having an upper face, the first electrode being light transmissive;
an organic light-emitting layer provided on the first electrode;
a second electrode provided on the organic light-emitting layer, the second electrode being light transmissive; and
a first wiring layer provided on the second electrode, the first wiring layer being light reflective, the first wiring layer including
a plurality of first wiring parts extending in a first direction parallel to the upper face and being arranged in a second direction, the second direction being parallel to the upper face and intersecting with the first direction, and
a plurality of second wiring parts extending in the second direction and being arranged in the first direction, the second wiring parts intersecting with each of the first wiring parts,
when a length of each of the first wiring parts in the second direction is set to W1 (micrometer),
a pitch of each of the first wiring parts is set to P1 (micrometer),
a length of each of the second wiring parts in the first direction is set to W2 (micrometer), and
a pitch of each of the second wiring parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.

12. An organic electroluminescent device, comprising:
a first electrode having an upper face, the first electrode being light transmissive;
an organic light-emitting layer provided on the upper face; and
a second electrode provided on the organic light-emitting layer, the second electrode being light reflective, the second electrode including
a plurality of first extension parts extending in a first direction parallel to the upper face and being arranged in a second direction, the second direction being parallel to the upper face and intersecting with the first direction, and
a plurality of second extension parts extending in the second direction and being arranged in the first direction, the second extension parts intersecting with each of the first extension parts,
when a length of each of the first extension parts in the second direction is set to W1 (micrometer),
a pitch of each of the first extension parts is set to P1 (micrometer),
a length of each of the second extension parts in the first direction is set to W2 (micrometer),
a pitch of each of the second extension parts is set to P2 (micrometer), and
the W1 and the W2 having different values,
the W1, the W2, the P1, and the P2 satisfying a relationship of max(W1, W2)≦−750×(1−max(W1/P1, W2/P2))²+675,
(1−max(W1/P1, W2/P2))² being not less than 0.55 and not more than 0.80, and
each of the W1 and the W2 being not less than 75 μm and not more than 225 μm.

13. An organic electroluminescent device, comprising:
a first electrode having an upper face, the first electrode being light transmissive;
an organic light-emitting layer provided on the first electrode;
a second electrode provided on the organic light-emitting layer, the second electrode being light transmissive; and
a first wiring layer provided between the first electrode and the organic light-emitting layer, the first wiring layer being light reflective, the first wiring layer including
a plurality of first wiring parts extending in a first direction parallel to the upper face and being arranged in a second direction, the second direction being parallel to the upper face and intersecting with the first direction, and
a plurality of second wiring parts extending in the second direction and being arranged in the first direction, the second wiring parts intersecting with each of the first wiring parts,
when a length of each of the first wiring parts in the second direction is set to W1 (micrometer),
a pitch of each of the first wiring parts is set to P1 (micrometer),
a length of each of the second wiring parts in the first direction is set to W2 (micrometer),
a pitch of each of the second wiring parts is set to P2 (micrometer), and
the W1 and the W2 having different values,
the W1, the W2, the P1, and the P2 satisfying a relationship of max(W1, W2)≦−750×(1−max(W1/P1, W2/P2))²+675,
(1−max(W1/P1, W2/P2))² being not less than 0.55 and not more than 0.80, and
each of the W1 and the W2 being not less than 75 μm and not more than 225 μm.

14. An organic electroluminescent device, comprising:
a first electrode having an upper face, the first electrode being light transmissive;
an organic light-emitting layer provided on the first electrode;
a second electrode provided on the organic light-emitting layer, the second electrode being light transmissive; and
a first wiring layer provided on the second electrode, the first wiring layer being light reflective, the first wiring layer including
a plurality of first wiring parts extending in a first direction parallel to the upper face and being arranged in a second direction, the second direction being parallel to the upper face and intersecting with the first direction, and
a plurality of second wiring parts extending in the second direction and being arranged in the first direction, the second wiring parts intersecting with each of the first wiring parts, and
when a length of each of the first wiring parts in the second direction is set to W1 (micrometer),
a pitch of each of the first wiring parts is set to P1 (micrometer),
a length of each of the second wiring parts in the first direction is set to W2 (micrometer),
a pitch of each of the second wiring parts is set to P2 (micrometer), and
the W1 and the W2 having different values,
the W1, the W2, the P1, and the P2 satisfying a relationship of max(W1, W2)≦−750×(1−max(W1/P1, W2/P2))²+675,
(1−max(W1/P1, W2/P2))² being not less than 0.55 and not more than 0.80, and
each of the W1 and the W2 being not less than 75 μm and not more than 225 μm.

15. An illumination apparatus comprising:
an organic electroluminescent device including:
a first electrode having an upper face, the first electrode being light transmissive;
an organic light-emitting layer provided on the upper face; and
a second electrode provided on the organic light-emitting layer, the second electrode being light reflective, the second electrode including
a plurality of first extension parts extending in a first direction parallel to the upper face and being arranged in a second direction, the second direction being parallel to the upper face and intersecting with the first direction, and
a plurality of second extension parts extending in the second direction and being arranged in the first direction, the second extension parts intersecting with each of the first extension parts; and
a power source electrically connected to the first electrode and the second electrode and supplying an electric current to the organic light-emitting layer through the first electrode and the second electrode,
when a length of each of the first extension parts in the second direction is set to W1 (micrometer),
a pitch of each of the first extension parts is set to P1 (micrometer),
a length of each of the second extension parts in the first direction is set to W2 (micrometer), and
a pitch of each of the second extension parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.

16. An illumination apparatus comprising:
an organic electroluminescent device including:
a first electrode having an upper face, the first electrode being light transmissive;
an organic light-emitting layer provided on the first electrode;
a second electrode provided on the organic light-emitting layer, the second electrode being light transmissive; and
a first wiring layer provided between the first electrode and the organic light-emitting layer, the first wiring layer being light reflective, the first wiring layer including
a plurality of first wiring parts extending in a first direction parallel to the upper face and being arranged in a second direction, the second direction being parallel to the upper face and intersecting with the first direction, and
a plurality of second wiring parts extending in the second direction and being arranged in the first direction, the second wiring parts intersecting with each of the first wiring parts; and
a power source electrically connected to the first electrode and the second electrode and supplying an electric current to the organic light-emitting layer through the first electrode and the second electrode,
when a length of each of the first wiring parts in the second direction is set to W1 (micrometer),
a pitch of each of the first wiring parts is set to P1 (micrometer),
a length of each of the second wiring parts in the first direction is set to W2 (micrometer), and
a pitch of each of the second wiring parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.

17. An illumination apparatus comprising:
an organic electroluminescent device including:
a first electrode having an upper face, the first electrode being light transmissive;
an organic light-emitting layer provided on the first electrode;
a second electrode provided on the organic light-emitting layer, the second electrode being light transmissive; and
a first wiring layer provided on the second electrode, the first wiring layer being light reflective, the first wiring layer including
a plurality of first wiring parts extending in a first direction parallel to the upper face and being arranged in a second direction, the second direction being parallel to the upper face and intersecting with the first direction, and
a plurality of second wiring parts extending in the second direction and being arranged in the first direction, the second wiring parts intersecting with each of the first wiring parts; and
a power source electrically connected to the first electrode and the second electrode and supplying an electric current to the organic light-emitting layer through the first electrode and the second electrode,
when a length of each of the first wiring parts in the second direction is set to W1 (micrometer),
a pitch of each of the first wiring parts is set to P1 (micrometer),
a length of each of the second wiring parts in the first direction is set to W2 (micrometer), and
a pitch of each of the second wiring parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.

18. An illumination system comprising:
a plurality of organic electroluminescent devices, each of the organic electroluminescent devices including:
a first electrode having an upper face, the first electrode being light transmissive;
an organic light-emitting layer provided on the upper face; and
a second electrode provided on the organic light-emitting layer, the second electrode being light reflective, the second electrode including
a plurality of first extension parts extending in a first direction parallel to the upper face and being arranged in a second direction, the second direction being parallel to the upper face and intersecting with the first direction, and
a plurality of second extension parts extending in the second direction and being arranged in the first direction, the second extension parts intersecting with each of the first extension parts; and
a controller electrically connected to each of the organic electroluminescent devices and controlling to turn on and turn off each of the organic electroluminescent devices,
when a length of each of the first extension parts in the second direction is set to W1 (micrometer),
a pitch of each of the first extension parts is set to P1 (micrometer),
a length of each of the second extension parts in the first direction is set to W2 (micrometer), and
a pitch of each of the second extension parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.

19. An illumination system comprising:
a plurality of organic electroluminescent devices, each of the organic electroluminescent devices including:
a first electrode having an upper face, the first electrode being light transmissive;
an organic light-emitting layer provided on the first electrode;
a second electrode provided on the organic light-emitting layer, the second electrode being light transmissive; and
a first wiring layer provided between the first electrode and the organic light-emitting layer, the first wiring layer being light reflective, the first wiring layer including
a plurality of first wiring parts extending in a first direction parallel to the upper face and being arranged in a second direction, the second direction being parallel to the upper face and intersecting with the first direction, and
a plurality of second wiring parts extending in the second direction and being arranged in the first direction, the second wiring parts intersecting with each of the first wiring parts; and
a controller electrically connected to each of the organic electroluminescent devices and controlling to turn on and turn off each of the organic electroluminescent devices,
when a length of each of the first wiring parts in the second direction is set to W1 (micrometer),
a pitch of each of the first wiring parts is set to P1 (micrometer),
a length of each of the second wiring parts in the first direction is set to W2 (micrometer), and
a pitch of each of the second wiring parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.

20. An illumination system comprising:
a plurality of organic electroluminescent devices, each of the organic electroluminescent devices including:
a first electrode having an upper face, the first electrode being light transmissive;
an organic light-emitting layer provided on the first electrode;
a second electrode provided on the organic light-emitting layer, the second electrode being light transmissive; and
a first wiring layer provided on the second electrode, the first wiring layer being light reflective, the first wiring layer including
a plurality of first wiring parts extending in a first direction parallel to the upper face and being arranged in a second direction, the second direction being parallel to the upper face and intersecting with the first direction, and
a plurality of second wiring parts extending in the second direction and being arranged in the first direction, the second wiring parts intersecting with each of the first wiring parts; and
a controller electrically connected to each of the organic electroluminescent devices and controlling to turn on and turn off each of the organic electroluminescent devices,
when a length of each of the first wiring parts in the second direction is set to W1 (micrometer),
a pitch of each of the first wiring parts is set to P1 (micrometer),
a length of each of the second wiring parts in the first direction is set to W2 (micrometer), and
a pitch of each of the second wiring parts is set to P2 (micrometer),
the W1 and the P1 satisfying a relationship of W1≦−750(1−W1/P1)(1−W2/P2)+675,
the W2 and the P2 satisfying a relationship of W2≦−750(1−W1/P1)(1−W2/P2)+675,
(1−W1/P1)(1−W2/P2) being not less than 0.55 and not more than 0.80, and
each of the W1 and the W2 being not less than 75 μm and not more than 225 μm.
